(19) United States
(12) Patent Application Publication
(10) Pub. No.: US 2026/0370195 A1
(43) Pub. Date: Nov. 19, 2026

(54) RADIO-FREQUENCY MODULE AND COMMUNICATION DEVICE

(71) Applicant: Murata Manufacturing Co., Ltd., Nagaokakyo-shi (JP)

(72) Inventors: Shogo YANASE, Nagaokakyo-shi (JP); Kazuhiro TAKAHASHI, Nagaokakyo-shi (JP); Kensuke TAKIMOTO, Nagaokakyo-shi (JP)

(73) Assignee: Murata Manufacturing Co., Ltd., Nagaokakyo-shi (JP)

(21) Appl. No.: 19/647,989

(22) Filed: Apr. 15, 2026

(30) Foreign Application Priority Data
May 19, 2025 (JP) 2025-083571

(51) Int. Cl. H03F 3/24; H03H 7/42

(52) U.S. Cl. CPC H03F 3/245; H03H 7/42; H03F 2200/451

(57) ABSTRACT

A radio-frequency module includes a mounting board and an IC chip. The IC chip includes a first to fourth power amplifiers. In a plan view from a thickness direction of the mounting board, a second balun is located on an inner side of a first balun and a primary coil of the second balun is located along a first side of the IC chip. Output terminals of the third and fourth power amplifiers 24 are disposed along the first side of the IC chip. Output terminals of the first and second power amplifiers are farther from the first side than the output terminals of the third and fourth power amplifiers.

### CROSS-REFERENCE TO RELATED APPLICATION

This application claims priority under 35 U.S.C. § 119 to Japanese Patent Application No. 2025-083571, filed on May 19, 2025, the entire contents of which are incorporated herein by reference.

### BACKGROUND

### 1. Field

The present disclosure generally relates to radio-frequency modules and communication devices, and more particularly to a radio-frequency module including a mounting board and to a communication device including the radio-frequency module.

### 2. Description of the Related Art

International Publication No. WO 2022/009748 discloses a radio-frequency module including a board, a first chip, a second chip, a first transformer, and a second transformer. The first chip and the second chip are disposed on a mounting surface of the board. The first transformer and the second transformer are formed inside the board.

In the radio-frequency module disclosed in WO2022/009748, the first chip includes a first amplifying element and a second amplifying element that amplify a first transmission signal. Additionally, the second chip includes a third amplifying element and a fourth amplifying element that amplify a second transmission signal. The first transformer includes a coil connected between an output terminal of the first amplifying element and an output terminal of the second amplifying element. The second transformer includes a coil connected between an output terminal of the third amplifying element and an output terminal of the fourth amplifying element.

### SUMMARY

A radio-frequency module according to one aspect of the present disclosure includes a mounting board and an IC chip. The IC chip is disposed on the mounting board. The IC chip includes a first power amplifier, a second power amplifier, a third power amplifier, and a fourth power amplifier. The first power amplifier amplifies a first radio-frequency signal of a first frequency. The second power amplifier amplifies a second radio-frequency signal that has a same frequency as the first frequency and is opposite in phase to the first radio-frequency signal. The third power amplifier amplifies a third radio-frequency signal of a second frequency higher than the first frequency. The fourth power amplifier amplifies a fourth radio-frequency signal that has a same frequency as the second frequency and is opposite in phase to the third radio-frequency signal. The mounting board includes a first balun and a second balun. The first balun includes a primary coil. The primary coil of the first balun is connected between an output terminal of the first power amplifier and an output terminal of the second power amplifier. The second balun includes a primary coil. The primary coil of the second balun is connected between an output terminal of the third power amplifier and an output terminal of the fourth power amplifier. The first balun further includes a secondary coil that faces the primary coil of the first balun in a thickness direction of the mounting board. The second balun further includes a secondary coil that faces the primary coil of the second balun in the thickness direction of the mounting board. In a plan view from the thickness direction of the mounting board, an outer edge of the IC chip has a rectangular shape. The outer edge of the IC chip includes a first side and a second side that are parallel to each other, and a third side and a fourth side that are parallel to each other. In a plan view from the thickness direction of the mounting board, the second balun is located on an inner side of the first balun. In a plan view from the thickness direction of the mounting board, the primary coil of the second balun is located along the first side of the IC chip. In the IC chip, the output terminal of the third power amplifier and the output terminal of the fourth power amplifier are disposed along the first side, and the output terminal of the first power amplifier and the output terminal of the second power amplifier are farther from the first side than the output terminal of the third power amplifier and the output terminal of the fourth power amplifier.

A communication device according to one aspect of the present disclosure includes the radio-frequency module of the aforementioned aspect and a signal processing circuit. The signal processing circuit is connected to the radio-frequency module.

The radio-frequency module and the communication device according to the aforementioned aspects of the present disclosure are capable of suppressing an increase in the plan-view aspect ratio of the IC chip including the four power amplifiers.

### BRIEF DESCRIPTION OF THE DRAWINGS

FIG. 1 is a plan view of the major components of a radio-frequency module according to Embodiment 1;

FIG. 2 is a perspective view of the major components of the aforementioned radio-frequency module;

FIG. 3 illustrates the aforementioned radio-frequency module, and is a cross-sectional view corresponding to the cross section taken along line III-III of FIG. 1;

FIG. 4 illustrates the aforementioned radio-frequency module, and is a cross-sectional view corresponding to the cross section taken along line IV-IV of FIG. 1;

FIG. 5 is a plan view of a first IC chip of the aforementioned radio-frequency module;

FIG. 6 is a partially cutaway plan view of the aforementioned radio-frequency module;

FIG. 7 is a circuit block diagram of a communication device including the aforementioned radio-frequency module;

FIG. 8 is a plan view of the major components of a radio-frequency module according to Embodiment 2;

FIG. 9 illustrates the aforementioned radio-frequency module, and is a cross-sectional view corresponding to the cross section taken along line IX-IX of FIG. 8;

FIG. 10 illustrates the aforementioned radio-frequency module, and is a cross-sectional view corresponding to the cross section taken along line X-X of FIG. 8;

FIG. 11 is a plan view of the major components of a radio-frequency module according to Embodiment 3;

FIG. 12 is a plan view of the major components of a radio-frequency module according to Embodiment 4;

FIG. 13 is a plan view of the major components of a radio-frequency module according to Embodiment 5;

FIG. 14 is a plan view of the major components of a radio-frequency module according to Embodiment 6; and

FIG. 15 illustrates the aforementioned radio-frequency module, and is a cross-sectional view corresponding to the cross section taken along line XV-XV of FIG. 14.

### DETAILED DESCRIPTION

In the configuration of the radio-frequency module disclosed in WO 2022/009748, the inventors have recognized that when the first amplifying element and the second amplifying element as well as the third amplifying element and the fourth amplifying element are integrated into a single IC chip, the aspect ratio of the outer edge of the rectangular shape of the IC chip in a plan view (=[length of the long side]/[length of the short side]) increases, and the connection reliability between the IC chip and the board on which the IC chip is mounted tends to decrease.

The present disclosure is directed to providing a radio-frequency module and a communication device capable of suppressing an increase in the plan-view aspect ratio of an IC chip including four power amplifiers.

Hereinafter, Embodiments 1 to 6 and the like will be described with reference to the drawings. The drawings referred to in Embodiments 1 to 6 and the like below are schematic diagrams, and the sizes and thicknesses of the elements in the drawings do not necessarily reflect actual dimensions. The ratios of the sizes and thicknesses among the elements do not necessarily reflect actual dimensional ratios.

### Embodiment 1

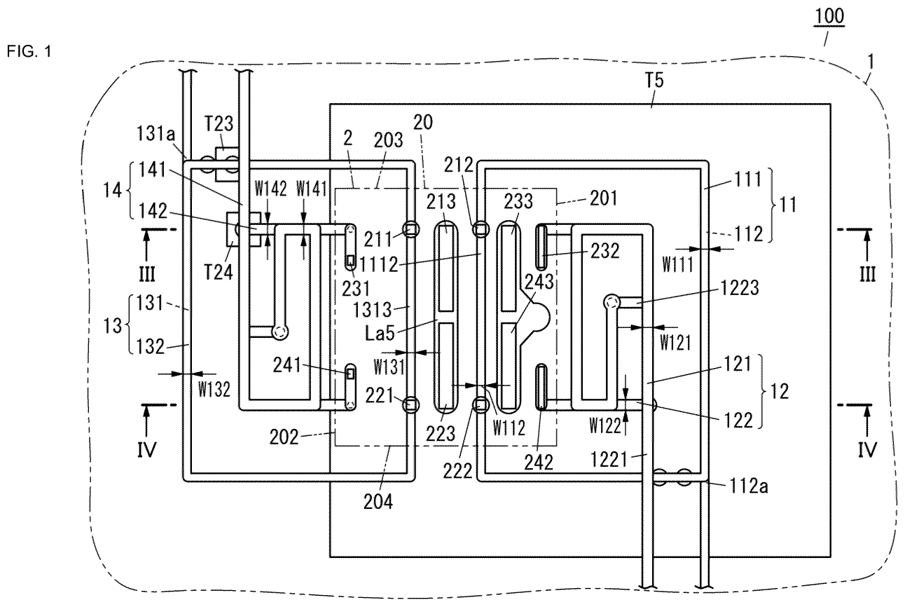

A radio-frequency module 100 and a communication device 500 according to Embodiment 1 will be described with reference to FIGS. 1 to 7.

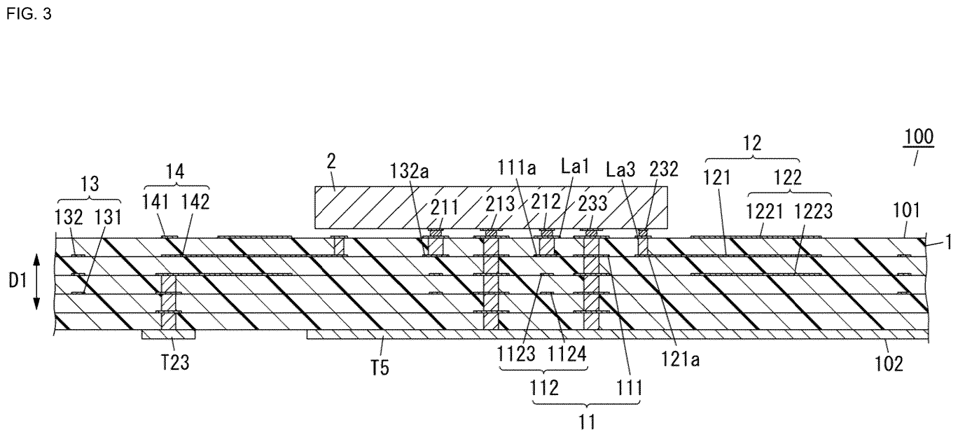

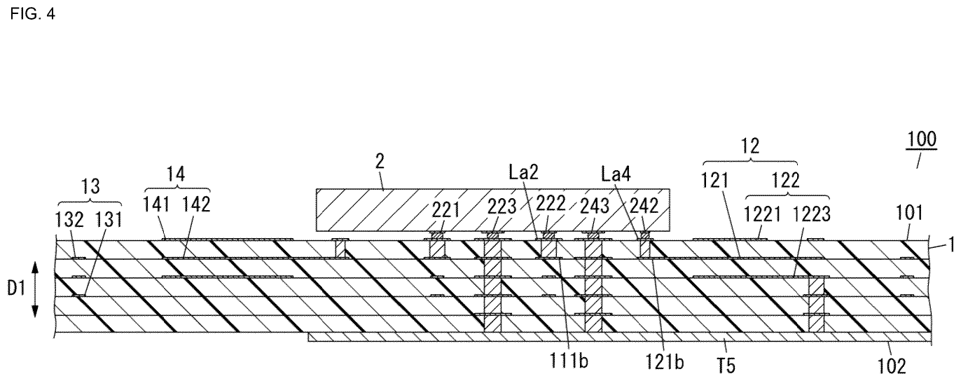

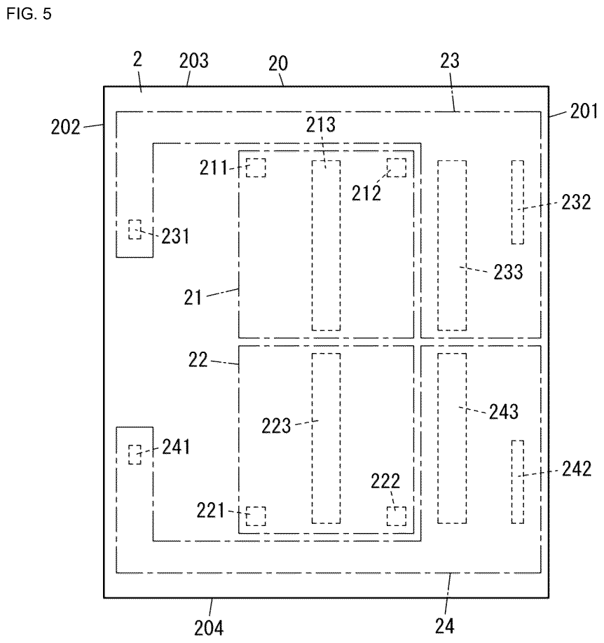

The radio-frequency module 100 according to Embodiment 1 includes a mounting board 1 and an IC chip 2, as illustrated in FIGS. 1 to 4. The IC chip 2 is disposed on the mounting board 1. The IC chip 2 includes a first power amplifier 21, a second power amplifier 22, a third power amplifier 23, and a fourth power amplifier 24, as illustrated in FIG. 5. The first power amplifier 21 amplifies a first radio-frequency signal of a first frequency. The second power amplifier 22 amplifies a second radio-frequency signal that has the same frequency as the first frequency and is opposite in phase to the first radio-frequency signal. The third power amplifier 23 amplifies a third radio-frequency signal of a second frequency higher than the first frequency. The fourth power amplifier 24 amplifies a fourth radio-frequency signal that has the same frequency as the second frequency and is opposite in phase to the third radio-frequency signal. As illustrated in FIGS. 1 to 3, the mounting board 1 includes a first balun 11 and a second balun 12. The first balun 11 includes a primary coil 111. The primary coil 111 of the first balun 11 is connected between an output terminal 212 of the first power amplifier 21 and an output terminal 222 of the second power amplifier 22. The second balun 12 includes a primary coil 121. The primary coil 121 of the second balun 12 is connected between an output terminal 232 of the third power amplifier 23 and an output terminal 242 of the fourth power amplifier 24. The first balun 11 further has a secondary coil 112 facing the primary coil 111 of the first balun 11 in a thickness direction D1 (see FIGS. 3 and 4) of the mounting board 1. The second balun 12 further has a secondary coil 122 facing the primary coil 121 of the second balun 12 in the thickness direction D1 of the mounting board 1.

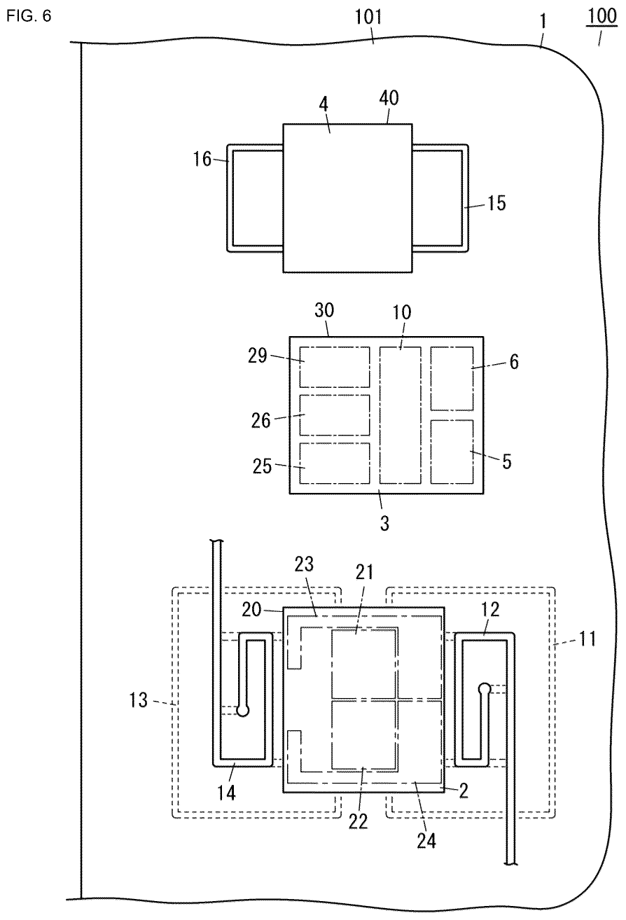

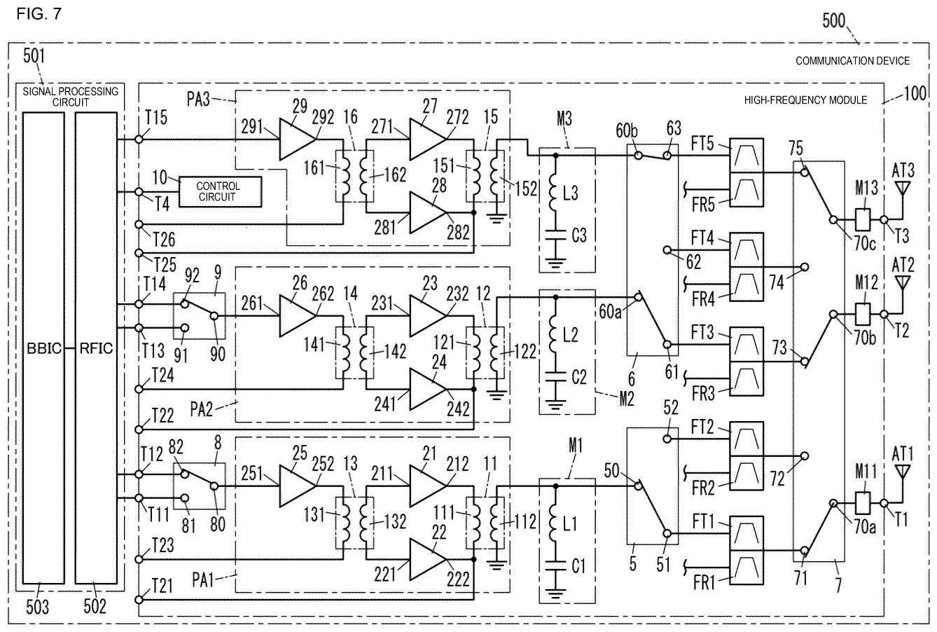

Additionally, the radio-frequency module 100 further includes a fifth power amplifier 25 and a sixth power amplifier 26, as illustrated in FIGS. 6 and 7.

The radio-frequency module 100 further includes a second IC chip 3 different from the IC chip 2 (hereinafter may also be referred to as the first IC chip 2), as illustrated in FIG. 6. The second IC chip 3 is disposed on the mounting board 1. In the present embodiment, the fifth power amplifier 25 and the sixth power amplifier 26 are included in the second IC chip 3.

The radio-frequency module 100 according to Embodiment 1 is used in the communication device 500, for example, as illustrated in FIG. 7. The communication device 500 is, but is not limited to, for example, a mobile phone (e.g., a smartphone), and may be, for example, a wearable terminal (e.g., a smart watch). The radio-frequency module 100 is a module capable of supporting, for example, the 4G (4 th Generation Mobile Communication System) standard, the 5G (5th Generation Mobile Communication System) standard, and the like. The 4G standard is, for example, the 3GPP (registered trademark, Third Generation Partnership Project) LTE (registered trademark, Long Term Evolution) standard. The 5G standard is, for example, 5G NR (New Radio). The radio-frequency module 100 is, for example, a module capable of handling carrier aggregation and dual connectivity.

The communication device 500 includes the radio-frequency module 100 and a signal processing circuit 501. The signal processing circuit 501 is connected to the radio-frequency module 100.

Hereinafter, the circuit configuration of the communication device 500 including the radio-frequency module 100 will be described based on FIG. 7, and then the configuration of the radio-frequency module 100 will be described in more detail.

### 1 Radio-Frequency Module

The radio-frequency module 100 includes a first power amplification circuit PA1, a second power amplification circuit PA2, a third power amplification circuit PA3, and a control circuit 10. The radio-frequency module 100 also includes a first matching circuit M1, a second matching circuit M2, a third matching circuit M3, a first switch 5 (hereinafter may also be referred to as a first band selection switch 5), and a second switch 6 (hereinafter may also be referred to as a second band selection switch 6). Additionally, the radio-frequency module 100 includes multiple (five in the example illustrated in FIG. 7) transmission filters FT1 to FT5, multiple (five in the example illustrated in FIG. 7) reception filters FR1 to FR5, a third switch 7 (hereinafter may also be referred to as an antenna switch 7), a fourth switch 8, and a fifth switch 9. Moreover, the radio-frequency module 100 includes a fourth matching circuit M11, a fifth matching circuit M12, a sixth matching circuit M13, and a low-noise amplification circuit. The radio-frequency module 100 also includes multiple external connection terminals. The multiple external connection terminals include five signal input terminals T11 to T15, four (only one is illustrated in FIG. 7) control terminals T4, six power supply terminals T21 to T26, a first antenna terminal T1, a second antenna terminal T2, a third antenna terminal T3, multiple signal output terminals, and multiple ground terminals.

### 1.1 First Power Amplification Circuit

In the present embodiment, the first power amplification circuit PA1 is an amplification circuit capable of handling a low-band communication band. The second power amplification circuit PA2 is an amplification circuit capable of handling a mid-band communication band. The third power amplification circuit PA3 is an amplification circuit capable of handling a radio-band communication band. The mid band is a frequency band higher than the low band. The high band is a frequency band higher than the mid band. The low band includes, for example, Band 8, Band 26, and Band 28 of the 3GPP (registered trademark, Third Generation Partnership Project) LTE (registered trademark, Long Term Evolution) standard. The mid band includes, for example, Band 1, Band 3, Band 34, and Band 39 of the 3GPP (registered trademark) LTE (registered trademark) standard. The high band includes, for example, Band 40 and Band 41 of the 3GPP (registered trademark) LTE (registered trademark) standard.

The first power amplification circuit PA1 is a differential amplification-type power amplification circuit that power-amplifies a first transmission signal of a first communication band and outputs it. The first power amplification circuit PA1 includes the fifth power amplifier 25, the first power amplifier 21, the second power amplifier 22, a third balun 13, and the first balun 11. The fifth power amplifier 25, the first power amplifier 21, and the second power amplifier 22 are power amplifiers capable of handling the low-band communication band. The gain of the fifth power amplifier 25 is smaller than the gain of each of the first power amplifier 21 and the second power amplifier 22.

The fifth power amplifier 25 is a drive-stage power amplifier in the first power amplification circuit PA1, and amplifies the first transmission signal (single-ended signal). The fifth power amplifier 25 includes at least one fifth transistor for amplification. The fifth transistor is, but is not limited to, for example, an FET (Field Effect Transistor), and may be a bipolar transistor. The fifth power amplifier 25 has an input terminal 251 and an output terminal 252. The input terminal 251 of the fifth power amplifier 25 is connected to the two signal input terminals T11 and T12 with the fourth switch 8 interposed therebetween. The output terminal 252 of the fifth power amplifier 25 is connected to the power supply terminal T23 with a primary coil 131 of the third balun 13 interposed therebetween. Note that the power supply terminal T23 is supplied with a first power supply voltage Vcc1 from an external power supply of the radio-frequency module 100.

The first power amplifier 21 is a last-stage power amplifier in the first power amplification circuit PA1, and includes at least one first transistor for amplification. The first transistor is, for example, an HBT (Heterojunction Bipolar Transistor). The first power amplifier 21 has an input terminal 211, the output terminal 212, and a ground terminal 213 (see FIG. 5). In the present embodiment, the input terminal 211 of the first power amplifier 21 is a base terminal of a first transistor, and the output terminal 212 of the first power amplifier 21 is a collector terminal of the first transistor. The ground terminal 213 of the first power amplifier 21 is an emitter terminal of the first transistor. The output terminal 212 of the first power amplifier 21 is connected to the power supply terminal T21 with the primary coil 111 of the first balun 11 interposed therebetween. Note that the power supply terminal T21 is supplied with a second power supply voltage Vcc2 from the external power supply of the radio-frequency module 100.

The second power amplifier 22 is a last-stage power amplifier in the first power amplification circuit PA1, and includes at least one second transistor for amplification. The second transistor is, for example, an HBT. The second power amplifier 22 has an input terminal 221, the output terminal 222, and a ground terminal 223 (see FIGS. 1 and 5). In the present embodiment, the input terminal 221 of the second power amplifier 22 is a base terminal of a second transistor, and the output terminal 222 of the second power amplifier 22 is a collector terminal of the second transistor. The ground terminal 223 of the second power amplifier 22 is an emitter terminal of the second transistor. The output terminal 222 of the second power amplifier 22 is connected to the power supply terminal T21.

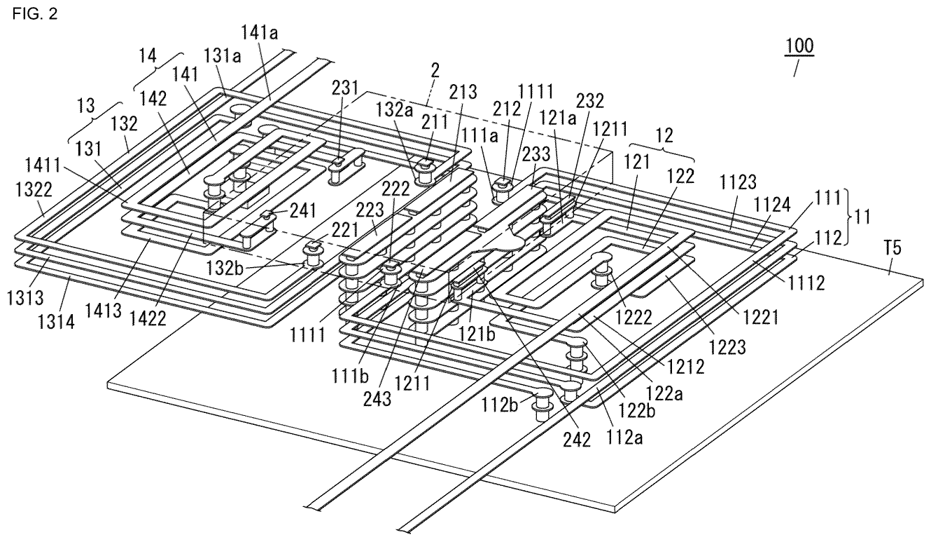

The third balun 13 has the primary coil 131 and a secondary coil 132. In the third balun 13, the secondary coil 132 is a coil couplable to the primary coil 131. The primary coil 131 of the third balun 13 is connected between the output terminal 252 of the fifth power amplifier 25 and the power supply terminal T23. The secondary coil 132 of the third balun 13 is connected between the input terminal 211 of the first power amplifier 21 and the input terminal 221 of the second power amplifier 22. The third balun 13 is capable of converting the first transmission signal (single-ended signal) input to a first end 131a (see FIG. 2) of the primary coil 131 into two signals (a first radio-frequency signal and a second radio-frequency signal) with phases opposite to each other, and outputting the first radio-frequency signal from a first end 132a of the secondary coil 132 and the second radio-frequency signal from a second end 132b (see FIG. 2) of the secondary coil 132. Thus, the third balun 13 distributes the first transmission signal (single-ended signal) amplified by the fifth power amplifier 25 into two signals (first radio-frequency signal and second radio-frequency signal) with phases opposite to each other. That is, the third balun 13 is capable of converting a single-ended signal into a differential signal.

The first balun 11 has the primary coil 111 and the secondary coil 112. In the first balun 11, the secondary coil 112 is a coil couplable to the primary coil 111. The primary coil 111 of the first balun 11 is connected between the output terminal 212 of the first power amplifier 21 and the output terminal 222 of the second power amplifier 22. A first end 112a (see FIG. 2) of the secondary coil 112 of the first balun 11 is connected to the two transmission filters FT1 and FT2 with the first matching circuit M1 and the first switch 5 interposed therebetween, and a second end 112b (see FIG. 2) of the secondary coil 112 is connected to the ground terminal T5. The first balun 11 is capable of converting the first radio-frequency signal input to a first end 111a (see FIG. 2) of the primary coil 111 and the second radio-frequency signal input to a second end 111b (see FIG. 2) of the primary coil 111 into a single-ended radio-frequency signal, and outputting it from the first end 112a of the secondary coil 112. Thus, the first balun 11 is capable of combining two signals with phases opposite to each other, respectively output from the first power amplifier 21 and the second power amplifier 22, into a single signal. That is, the first balun 11 is capable of converting a differential signal into a single-ended signal.

### 1.2 Second Power Amplification Circuit

The second power amplification circuit PA2 is a differential amplification-type power amplification circuit that power-amplifies a second transmission signal of a second communication band and outputs it. The second power amplification circuit PA2 includes the sixth power amplifier 26, the third power amplifier 23, the fourth power amplifier 24, a fourth balun 14, and the second balun 12. The sixth power amplifier 26, the third power amplifier 23, and the fourth power amplifier 24 are power amplifiers capable of handling the mid-band communication band. The gain of the sixth power amplifier 26 is smaller than the gain of each of the third power amplifier 23 and the fourth power amplifier 24.

The sixth power amplifier 26 is a drive-stage power amplifier in the second power amplification circuit PA2, and amplifies the second transmission signal (single-ended signal). The sixth power amplifier 26 includes at least one sixth transistor for amplification. The sixth transistor is, but is not limited to, for example, an FET, and may be a bipolar transistor. The sixth power amplifier 26 has an input terminal 261 and an output terminal 262. The input terminal 261 of the sixth power amplifier 26 is connected to the two signal input terminals T13 and T14 with the fifth switch 9 interposed therebetween. The output terminal 262 of the sixth power amplifier 26 is connected to the power supply terminal T24 with a primary coil 141 of the fourth balun 14 interposed therebetween. Note that the power supply terminal T24 is supplied with the first power supply voltage Vcc1 from the external power supply of the radio-frequency module 100.

The third power amplifier 23 is a last-stage power amplifier in the second power amplification circuit PA2, and includes at least one third transistor for amplification. The third transistor is, for example, an HBT. The third power amplifier 23 has an input terminal 231, the output terminal 232, and a ground terminal 233 (see FIG. 1). In the present embodiment, the input terminal 231 of the third power amplifier 23 is a base terminal of a third transistor, and the output terminal 232 of the third power amplifier 23 is a collector terminal of the third transistor. The ground terminal 233 of the third power amplifier 23 is an emitter terminal of the third transistor. The output terminal 232 of the third power amplifier 23 is connected to the power supply terminal T22 with the primary coil 131 of the second balun 12 interposed therebetween. Note that the power supply terminal T22 is supplied with the second power supply voltage Vcc2 from the external power supply of the radio-frequency module 100.

The fourth power amplifier 24 is a last-stage power amplifier in the second power amplification circuit PA2, and includes at least one fourth transistor for amplification. The fourth transistor is, for example, an HBT. The fourth power amplifier 24 has an input terminal 241, the output terminal 242, and a ground terminal 243 (see FIGS. 1 and 5). In the present embodiment, the input terminal 241 of the fourth power amplifier 24 is a base terminal of the fourth transistor, and the output terminal 242 of the fourth power amplifier 24 is a collector terminal of the fourth transistor. The ground terminal 243 of the fourth power amplifier 24 is an emitter terminal of the fourth transistor. The output terminal 242 of the fourth power amplifier 24 is connected to the power supply terminal T22.

The fourth balun 14 has the primary coil 141 and a secondary coil 142. In the fourth balun 14, the secondary coil 142 is a coil couplable to the primary coil 141. The primary coil 141 of the fourth balun 14 is connected between the output terminal 262 of the sixth power amplifier 26 and the power supply terminal T24. The secondary coil 142 is connected between the input terminal 231 of the third power amplifier 23 and the input terminal 241 of the fourth power amplifier 24. The fourth balun 14 is capable of converting the second transmission signal (single-ended signal) input to a first end 141a of the primary coil 141 into two signals (a third radio-frequency signal and a fourth radio-frequency signal) with phases opposite to each other, and outputting the third radio-frequency signal from a first end of the secondary coil 142 and the fourth radio-frequency signal from a second end of the secondary coil 142. Thus, the fourth balun 14 distributes the second transmission signal (single-ended signal) amplified by the sixth power amplifier 26 into two signals (third radio-frequency signal and fourth radio-frequency signal) with phases opposite to each other. That is, the fourth balun 14 is capable of converting a single-ended signal into a differential signal.

The second balun 12 has the primary coil 121 and the secondary coil 122. In the second balun 12, the secondary coil 122 is a secondary coil couplable to the primary coil 121. The primary coil 121 of the second balun 12 is connected between the output terminal 232 of the third power amplifier 23 and the output terminal 242 of the fourth power amplifier 24. A first end 122a (see FIG. 2) of the secondary coil 122 is connected to the two transmission filters FT3 and FT4 with the second matching circuit M2 and the second switch 6 interposed therebetween. A second end 122b (see FIG. 2) of the secondary coil 122 is connected to the ground terminal T5. The second balun 12 is capable of converting the radio-frequency signals (third radio-frequency signal and fourth radio-frequency signal) with phases opposite to each other, respectively input to a first end 121a and a second end 121b of the primary coil 121, into a single-ended radio-frequency signal, and outputting it from the first end 122a of the secondary coil 122. Thus, the second balun 12 is capable of combining the two signals with phases opposite to each other, respectively output from the third power amplifier 23 and the fourth power amplifier 24, into a single signal. That is, the second balun 12 is capable of converting a differential signal into a single-ended signal.

### 1.3 Third Power Amplification Circuit

The third power amplification circuit PA3 is a differential amplification-type power amplification circuit that power-amplifies a third transmission signal of a third communication band and outputs it. The third power amplification circuit PA3 includes a ninth power amplifier 29, a seventh power amplifier 27, an eighth power amplifier 28, a sixth balun 16, and a fifth balun 15. The ninth power amplifier 29, the seventh power amplifier 27, and the eighth power amplifier 28 are power amplifiers capable of handling the radio-band communication band. The gain of the ninth power amplifier 29 is smaller than the gain of each of the seventh power amplifier 27 and the eighth power amplifier 28.

The ninth power amplifier 29 is a drive-stage power amplifier that amplifies the third transmission signal (single-ended signal), and includes a ninth transistor for amplification. The ninth transistor is, but is not limited to, for example, an FET, and may be a bipolar transistor. The ninth power amplifier 29 has an input terminal 291 and an output terminal 292. The input terminal 291 of the ninth power amplifier 29 is connected to the signal input terminal T15. The output terminal 292 of the ninth power amplifier 29 is connected to the power supply terminal T26 with a primary coil 161 of the sixth balun 16 interposed therebetween. Note that the power supply terminal T26 is supplied with the first power supply voltage Vcc1 from the external power supply of the radio-frequency module 100.

The seventh power amplifier 27 is a last-stage power amplifier in the third power-amplifying circuit PA3, and includes a seventh transistor for amplification. The seventh transistor is, for example, an HBT. The seventh power amplifier 27 has an input terminal 271, an output terminal 272, and a ground terminal. In the present embodiment, the input terminal 271 of the seventh power amplifier 27 is a base terminal of the seventh transistor, and the output terminal 272 of the seventh power amplifier 27 is a collector terminal of the seventh transistor. The ground terminal of the seventh power amplifier 27 is an emitter terminal of the seventh transistor. The output terminal 272 of the seventh power amplifier 27 is connected to the power supply terminal T25 with a primary coil 151 of the fifth balun 15 interposed therebetween. Note that the power supply terminal T25 is supplied with the first power supply voltage Vcc1 from the external power supply of the radio-frequency module 100.

The eighth power amplifier 28 is a last-stage power amplifier in the third power amplification circuit PA3, and includes an eighth transistor for amplification. The eighth transistor is, for example, an HBT. The eighth power amplifier 28 has an input terminal 281, an output terminal 282, and a ground terminal. In the present embodiment, the input terminal 281 of the eighth power amplifier 28 is a base terminal of the eighth transistor, and the output terminal 282 of the eighth power amplifier 28 is a collector terminal of the eighth transistor. The ground terminal of the eighth power amplifier 28 is an emitter terminal of the eighth transistor. The output terminal 282 of the eighth power amplifier 28 is connected to the power supply terminal T25.

The sixth balun 16 has the primary coil 161 and a secondary coil 162. In the sixth balun 16, the secondary coil 162 is a coil couplable to the primary coil 161. The primary coil 161 of the sixth balun 16 is connected between the output terminal 292 of the ninth power amplifier 29 and the power supply terminal T26. The secondary coil 162 of the sixth balun 16 is connected between the input terminal 271 of the seventh power amplifier 27 and the input terminal 281 of the eighth power amplifier 28. The sixth balun 16 is capable of converting the third transmission signal (single-ended signal) input to a first end of the primary coil 161 into two signals (a fifth radio-frequency signal and a sixth radio-frequency signal) with phases opposite to each other, and outputting the fifth radio-frequency signal from a first end of the secondary coil 162 and the sixth radio-frequency signal from a second end of the secondary coil 162. Thus, the sixth balun 16 distributes the third transmission signal (single-ended signal) amplified by the ninth power amplifier 29 into two signals with phases opposite to each other. That is, the sixth balun 16 is capable of converting a single-ended signal into a differential signal.

The fifth balun 15 has the primary coil 151 and a secondary coil 152. In the fifth balun 15, the secondary coil 152 is a coil couplable to the primary coil 151. The primary coil 151 is connected between the output terminal 272 of the seventh power amplifier 27 and the output terminal 282 of the eighth power amplifier 28. A first end of the secondary coil 152 of the fifth balun 15 is connected to the transmission filter FT5 with the third matching circuit M3 and the second switch 6 interposed therebetween, and a second end of the secondary coil 152 is connected to ground. The fifth balun 15 is capable of converting radio-frequency signals (first radio-frequency signal and second radio-frequency signal) with phases opposite to each other, respectively input to the first and second ends of the primary coil 151, into a single-ended radio-frequency signal, and outputting it from the first end of the secondary coil 152. Thus, the fifth balun 15 is capable of combining the two signals with phases opposite to each other, respectively output from the seventh power amplifier 27 and the eighth power amplifier 28, into a single signal. That is, the fifth balun 15 is capable of converting a differential signal into a single-ended signal.

### 1.4 Control Circuit

The control circuit 10 controls the first power amplification circuit PA1, the second power amplification circuit PA2, and the third power amplification circuit PA3. The control circuit 10 controls, for example, the first power amplifier 21, the second power amplifier 22, the third power amplifier 23, the fourth power amplifier 24, the fifth power amplifier 25, the sixth power amplifier 26, the seventh power amplifier 27, the eighth power amplifier 28, and the ninth power amplifier 29 in accordance with control signals from the signal processing circuit 501. The control circuit 10 is connected to the signal processing circuit 501, for example, with four (only one is illustrated in FIG. 7) control terminals T4 interposed therebetween.

### 1.5 First Matching Circuit, Second Matching Circuit, and Third Matching Circuit

The first matching circuit M1 is a matching circuit for impedance matching between the first balun 11 and the first switch 5. The first matching circuit M1 is connected between the first end 112a (see FIG. 2) of the secondary coil 112 of the first balun 11 and a common terminal 50 of the first switch 5. The first matching circuit M1 includes, for example, a first inductor L1 and a first capacitor C1.

The second matching circuit M2 is a matching circuit for impedance matching between the second balun 12 and the second switch 6. The second matching circuit M2 is connected between the first end 122a (see FIG. 2) of the secondary coil 122 of the second balun 12 and a common terminal 60a of the second switch 6. The second matching circuit M2 includes, for example, a second inductor L2 and a second capacitor C2.

The third matching circuit M3 is a matching circuit for impedance matching between the fifth balun 15 and the second switch 6. The third matching circuit M3 is connected between the first end of the secondary coil 152 of the fifth balun 15 and a common terminal 60b of the second switch 6. The third matching circuit M3 includes, for example, a third inductor L3 and a third capacitor C3.

### 1.6 Transmission Filters

The transmission filter FT1 (hereinafter may also be referred to as the first transmission filter FT1) is a band-pass filter having a passband that includes a transmission band of the first communication band. The first communication band is included, for example, in the low band. The first communication band is, for example, Band 8 of the 3GPP LTE standard. An input terminal of the first transmission filter FT1 is connected to a selection terminal 51 of the first switch 5, and an output terminal of the first transmission filter FT1 is connected to a selection terminal 71 of the third switch 7.

The transmission filter FT2 (hereinafter may also be referred to as the second transmission filter FT2) is a band-pass filter having a passband that includes a transmission band of the second communication band. The second communication band is included, for example, in the low band. The second communication band is, for example, Band 26 of the 3GPP LTE standard. An input terminal of the second transmission filter FT2 is connected to a selection terminal 52 of the first switch 5, and an output terminal of the second transmission filter FT2 is connected to a selection terminal 72 of the third switch 7.

The transmission filter FT3 (hereinafter may also be referred to as the third transmission filter FT3) is a band-pass filter having a passband that includes a transmission band of the third communication band. The third communication band is included, for example, in the mid band. The third communication band is, for example, Band 39 of the 3GPP LTE standard. An input terminal of the third transmission filter FT3 is connected to a selection terminal 61 of the second switch 6, and an output terminal of the third transmission filter FT3 is connected to a selection terminal 73 of the third switch 7.

The transmission filter FT4 (hereinafter may also be referred to as the fourth transmission filter FT4) is a band-pass filter having a passband that includes a transmission band of the fourth communication band. The fourth communication band is included, for example, in the mid band. The fourth communication band is, for example, Band 34 of the 3GPP LTE standard. An input terminal of the fourth transmission filter FT4 is connected to a selection terminal 62 of the second switch 6, and an output terminal of the fourth transmission filter FT4 is connected to a selection terminal 74 of the third switch 7.

The transmission filter FT5 (hereinafter may also be referred to as the fifth transmission filter FT5) is a band-pass filter having a passband that includes a transmission band of the fifth communication band. The fifth communication band is included in, for example, the high band. The fifth communication band is, for example, Band 40 of the 3GPP LTE standard. An input terminal of the fifth transmission filter FT5 is connected to a selection terminal 63 of the second switch 6, and an output terminal of the fifth transmission filter FT5 is connected to a selection terminal 75 of the third switch 7.

### 1.7 Reception Filters

The reception filter FR1 (hereinafter may also be referred to as the first reception filter FR1) is a band-pass filter having a passband that includes a reception band of the first communication band. An input terminal of the first reception filter FR1 is connected to the selection terminal 71 of the third switch 7, and an output terminal of the first reception filter FR1 is connected to the low-noise amplification circuit.

The reception filter FR2 (hereinafter may also be referred to as the second reception filter FR2) is a band-pass filter having a passband that includes a reception band of the second communication band. An input terminal of the second reception filter FR2 is connected to the selection terminal 72 of the third switch 7, and an output terminal of the second reception filter FR2 is connected to the low-noise amplification circuit.

The reception filter FR3 (hereinafter may also be referred to as the third reception filter FR3) is a band-pass filter having a passband that includes a reception band of the third communication band. An input terminal of the third reception filter FR3 is connected to the selection terminal 73 of the third switch 7, and an output terminal of the third reception filter FR3 is connected to the low-noise amplification circuit.

The reception filter FR4 (hereinafter may also be referred to as the fourth reception filter FR4) is a band-pass filter having a passband that includes a reception band of the fourth communication band. An input terminal of the fourth reception filter FR4 is connected to the selection terminal 74 of the third switch 7, and an output terminal of the fourth reception filter FR4 is connected to the low-noise amplification circuit.

The reception filter FR5 (hereinafter may also be referred to as the fifth reception filter FR5) is a band-pass filter having a passband that includes a reception band of the fifth communication band. An input terminal of the fifth reception filter FR5 is connected to the selection terminal 75 of the third switch 7, and an output terminal of the fifth reception filter FR5 is connected to the low-noise amplification circuit.

### 1.8 First Switch

The first switch 5 has the common terminal 50 and the multiple (two in the example illustrated in FIG. 7) selection terminals 51 and 52. In the first switch 5, the common terminal 50 is connected to the first end 112a of the secondary coil 112 of the first balun 11 with the first matching circuit M1 interposed therebetween. Additionally, the selection terminal 51 is connected to the first transmission filter FT1. Moreover, the selection terminal 52 is connected to the second transmission filter FT2. The first switch 5 is, for example, a switch capable of connecting at least one of the multiple selection terminals 51 and 52 to the common terminal 50. The first switch 5 is, for example, a switch capable of establishing one-to-one and one-to-many connections. The first switch 5 is, for example, controlled by the signal processing circuit 501. In more detail, the first switch 5 is a switch circuit capable of switching a connection state between the common terminal 50 and the multiple selection terminals 51 and 52 in accordance with a control signal from an RF signal processing circuit 502 of the signal processing circuit 501.

### 1.9 Second Switch

The second switch 6 has, for example, the two common terminals 60a and 60b and the multiple (three in the example illustrated in FIG. 7) selection terminals 61 to 63.

In the second switch 6, the common terminal 60a (hereinafter may also be referred to as the first common terminal 60a) is connected to the first end 122a of the secondary coil 122 of the second balun 12 with the second matching circuit M2 interposed therebetween. Additionally, the common terminal 60b (hereinafter may also be referred to as the second common terminal 60b) is connected to the first end of the secondary coil 152 of the fifth balun 15 with the third matching circuit M3 interposed therebetween. Moreover, the selection terminal 61 is connected to the input terminal of the third transmission filter FT3. Furthermore, the selection terminal 62 is connected to the input terminal of the fourth transmission filter FT4. Additionally, the selection terminal 63 is connected to the input terminal of the fifth transmission filter FT5. The second switch 6 is, for example, a switch capable of connecting at least one of the selection terminals 61 and 62 to the first common terminal 60a, and capable of connecting the selection terminal 63 to the second common terminal 60b. The second switch 6 is, for example, controlled by the signal processing circuit 501. The second switch 6 is a switch circuit for switching a connection state between the common terminals 60a and 60b and the multiple selection terminals 61, 62, and 63 in accordance with a control signal from the RF signal processing circuit 502 of the signal processing circuit 501.

### 1.10 Third Switch

The third switch 7 is an antenna switch connected to the multiple (three in the example illustrated in FIG. 7) antenna terminals T1, T2, and T3. The third switch 7 has three common terminals 70a, 70b, and 70c, and the multiple (five in the example illustrated in FIG. 7) selection terminals 71 to 75.

In the third switch 7, the common terminal 70a (hereinafter may also be referred to as the first common terminal 70a) is connected to the first antenna terminal T1 with the fourth matching circuit M11 interposed therebetween. Additionally, the common terminal 70b (hereinafter may also be referred to as the second common terminal 70b) is connected to the second antenna terminal T2 with the fifth matching circuit M12 interposed therebetween. Moreover, the common terminal 70c (hereinafter may also be referred to as the third common terminal 70c) is connected to the third antenna terminal T3 with the sixth matching circuit M13 interposed therebetween. Furthermore, the selection terminal 71 is connected to the output terminal of the first transmission filter FT1 and the input terminal of the first reception filter FR1. Additionally, the selection terminal 72 is connected to the output terminal of the second transmission filter FT2 and the input terminal of the second reception filter FR2. Moreover, the selection terminal 73 is connected to the output terminal of the third transmission filter FT3 and the input terminal of the third reception filter FR3. Furthermore, the selection terminal 74 is connected to the output terminal of the fourth transmission filter FT4 and the input terminal of the fourth reception filter FR4. Additionally, the selection terminal 75 is connected to the output terminal of the fifth transmission filter FT5 and the input terminal of the fifth reception filter FR5. The third switch 7 is, for example, a switch capable of connecting at least one of the selection terminals 71 and 72 to the first common terminal 70a, capable of connecting at least one of the selection terminals 73 and 74 to the second common terminal 70b, and capable of connecting the selection terminal 75 to the third common terminal 70c. The third switch 7 is, for example, controlled by the signal processing circuit 501. The third switch 7 is a switch circuit for switching a connection state between the common terminals 70a, 70b, and 70c and the multiple selection terminals 71, 72, 73, 74, and 75 in accordance with a control signal from the RF signal processing circuit 502 of the signal processing circuit 501.

### 1.11 Fourth Switch

The fourth switch 8 has a common terminal 80 and multiple (two in the example illustrated in FIG. 7) selection terminals 81 and 82. In the fourth switch 8, the common terminal 80 is connected to the input terminal 251 of the fifth power amplifier 25. In the fourth switch 8, the two selection terminals 81 and 82 are connected to the signal input terminals T11 and T12, respectively. The fourth switch 8 is, for example, a switch capable of connecting at least one of the multiple selection terminals 81 and 82 to the common terminal 80. The fourth switch 8 is, for example, controlled by the signal processing circuit 501. The fourth switch 8 is a switch circuit for switching a connection state between the common terminal 80 and the multiple selection terminals 81 and 82 in accordance with a control signal from the RF signal processing circuit 502 of the signal processing circuit 501.

### 1.12 Fifth Switch

The fifth switch 9 has a common terminal 90 and multiple (two in the example illustrated in FIG. 7) selection terminals 91 and 92. In the fifth switch 9, the common terminal 90 is connected to the input terminal 261 of the sixth power amplifier 26. In the fifth switch 9, the two selection terminals 91 and 92 are connected to the signal input terminals T13 and T14, respectively. The fifth switch 9 is, for example, a switch capable of connecting at least one of the multiple selection terminals 91 and 92 to the common terminal 90. The fifth switch 9 is, for example, controlled by the signal processing circuit 501. The fifth switch 9 is a switch circuit for switching a connection state between the common terminal 90 and the multiple selection terminals 91 and 92 in accordance with a control signal from the RF signal processing circuit 502 of the signal processing circuit 501.

### 1.13 Fourth Matching Circuit, Fifth Matching Circuit, and Sixth Matching Circuit

The fourth matching circuit M11 is a matching circuit for impedance matching between the antenna switch 7 and the first antenna terminal T1. The fourth matching circuit M11 is connected between the common terminal 70a of the antenna switch 7 and the first antenna terminal T1. The fourth matching circuit M11 includes, for example, an inductor and a capacitor.

The fifth matching circuit M12 is a matching circuit for impedance matching between the antenna switch 7 and the second antenna terminal T2. The fifth matching circuit M12 is connected between the common terminal 70b of the antenna switch 7 and the second antenna terminal T2. The fifth matching circuit M12 includes, for example, an inductor and a capacitor.

The sixth matching circuit M13 is a matching circuit for impedance matching between the antenna switch 7 and the third antenna terminal T3. The sixth matching circuit M13 is connected between the common terminal 70c of the antenna switch 7 and the third antenna terminal T3. The sixth matching circuit M13 includes, for example, an inductor and a capacitor.

### 1.14 Low-Noise Amplification Circuit

The low-noise amplification circuit includes multiple low-noise amplifiers and a switch, and is configured to be capable of amplifying reception signals respectively from the multiple reception filters FR1 to FR5 with low noise and outputting them. The low-noise amplification circuit is connected to multiple signal output terminals. The multiple signal output terminals are, for example, connected to the signal processing circuit 501.

### 2 Structure of Radio-Frequency Module

Hereinafter, the structure of the radio-frequency module 100 according to the present embodiment will be described with reference to FIGS. 1 to 6.

The radio-frequency module 100 includes the mounting board 1 and multiple electronic components. The multiple electronic components include the IC chip 2 (first IC chip 2) and the second IC chip 3. In FIG. 6, among the multiple components, the first IC chip 2, the second IC chip 3, and a third IC chip 4 are illustrated.

### 2.1 Mounting Board

The mounting board 1 has a first main surface 101 and a second main surface 102, as illustrated in FIGS. 3 and 4. The first main surface 101 and the second main surface 102 face each other. In more detail, the first main surface 101 and the second main surface 102 face each other in the thickness direction D1 of the mounting board 1. The mounting board 1 is a board for disposing multiple electronic components, and has, for example, a rectangular plate shape. The first main surface 101 and the second main surface 102 have, for example, a rectangular shape. When the radio-frequency module 100 is mounted on an external board (for example, a motherboard), the second main surface 102 of the mounting board 1 faces the external board.

The mounting board 1 has multiple dielectric layers and multiple conductive layers. The mounting board 1 is, for example, a multilayer board having multiple dielectric layers and multiple conductive layers. The multiple dielectric layers and the multiple conductive layers are stacked in the thickness direction D1 of the mounting board 1.

Each of the multiple conductive layers includes one or more conductive portions in a plane orthogonal to the thickness direction D1 of the mounting board 1. The multiple conductive layers are formed in a predetermined pattern defined for each layer. The material of each conductive layer is, for example, copper. The mounting board 1 also has multiple via conductors. Hereinafter, when describing the multiple conductive layers separately for each layer, the multiple conductive layers may also be referred to as a first conductive layer, a second conductive layer, a third conductive layer, a fourth conductive layer, a fifth conductive layer, and a sixth conductive layer, in the order from a side closer to the IC chip 2 in the thickness direction D1 of the mounting board 1.

The multiple conductive layers include a ground layer. The ground layer is a layer to which a ground potential (reference potential) is applied, and is provided inside the mounting board 1. When the radio-frequency module 100 is mounted on an external board (for example, a motherboard), the ground layer is connected to a ground of the external board with the via conductors and the like, provided in the mounting board 1, interposed therebetween, and is maintained at a ground potential.

The mounting board 1 is, for example, a printed wiring board. The mounting board 1 is not limited to a printed wiring board, and may be, for example, an LTCC (Low Temperature Co-fired Ceramics) substrate, an HTCC (High Temperature Co-fired Ceramics) substrate, or a resin multilayer substrate.

In the present embodiment, the mounting board 1 includes the first balun 11, the second balun 12, the third balun 13, the fourth balun 14, the fifth balun 15, and the sixth balun 16. In each of the first to sixth baluns 11 to 16, the expression “the line width of the secondary coil is the same as the line width of the primary coil in a plan view from the thickness direction D1 of the mounting board 1” is not limited to a case where the line width of the secondary coil is 100% of the line width of the primary coil, and may include a case where the line width of the secondary coil is within a range of 90% to 110% of the line width of the primary coil 111.

In the first balun 11, the secondary coil 112 faces the primary coil 111 in the thickness direction D1 of the mounting board 1. In the present embodiment, in a plan view from the thickness direction D1 of the mounting board 1, a line width W112 of the secondary coil 112 is the same as a line width W111 of the primary coil 111. In the first balun 11, a portion of the secondary coil 112 overlaps a portion of the primary coil 111 in a plan view from the thickness direction D1 of the mounting board 1. In the first balun 11 of the present embodiment, the primary coil 111 includes one conductive portion 1112 layer (see FIG. 2) of the second conductive layer. The secondary coil 112 includes one conductive portion 1123 (see FIG. 2) of the third conductive layer and one conductive portion 1124 (see FIG. 2) of the fourth conductive layer. In the first balun 11, the number of turns of the primary coil 111 is less than one, and the number of turns of the secondary coil 112 is two. Note that the number of turns of the primary coil 111 is not limited to being less than one, and may be one or more.

The first end 111a of the primary coil 111 of the first balun 11 is connected to the output terminal 212 of the first power amplifier 21. In more detail, the first end 111a of the primary coil 111 of the first balun 11 is connected to the output terminal 212 of the first power amplifier 21 with a land electrode La1 or the like of the mounting board 1 interposed therebetween. The second end 111b of the primary coil 111 is connected to the output terminal 222 of the second power amplifier 22. In more detail, the second end 111b of the primary coil 111 is connected to the output terminal 222 of the second power amplifier 22 with a land electrode La2 or the like of the mounting board 1 interposed therebetween. The first end 112a of the secondary coil 112 is connected to the common terminal 50 of the first switch 5. The second end 112b of the secondary coil 112 is connected to the ground terminal T5.

In the second balun 12, the secondary coil 122 faces the primary coil 121 in the thickness direction D1 of the mounting board 1. In the present embodiment, in a plan view from the thickness direction D1 of the mounting board 1, a line width W122 of the secondary coil 122 is the same as a line width W121 of the primary coil 121. In the second balun 12, a portion of the secondary coil 122 overlaps a portion of the primary coil 121 in a plan view from the thickness direction D1 of the mounting board 1. In the second balun 12 of the present embodiment, the primary coil 121 includes one conductive portion 1212 of the second conductive layer. The secondary coil 122 includes one conductive portion 1221 (see FIG. 2) of the first conductive layer, one conductive portion 1222 (see FIG. 2) of the second conductive layer, and one conductive portion 1223 (see FIG. 2) of the third conductive layer. In the second balun 12, the number of turns of the primary coil 121 is less than one, and the number of turns of the secondary coil 122 is two. Note that the number of turns of the primary coil 121 is not limited to being less than one, and may be one or more.

The first end 121a of the primary coil 121 of the second balun 12 is connected to the output terminal 232 of the third power amplifier 23. In more detail, the first end 121a of the primary coil 121 is connected to the output terminal 232 of the third power amplifier 23 with a land electrode La3 or the like of the mounting board 1 interposed therebetween. The second end 121b of the primary coil 121 is connected to the output terminal 242 of the fourth power amplifier 24. In more detail, the second end 121b of the primary coil 121 is connected to the output terminal 242 of the fourth power amplifier 24 with a land electrode La4 or the like of the mounting board 1 interposed therebetween. The first end 122a of the secondary coil 122 is connected to the common terminal 60b of the second switch 6. The second end 122b of the secondary coil 122 is connected to the ground terminal T5.

In the third balun 13, the secondary coil 132 faces the primary coil 131 in the thickness direction D1 of the mounting board 1. In the present embodiment, in a plan view from the thickness direction D1 of the mounting board 1, a line width W132 of the secondary coil 132 is the same as a line width W131 of the primary coil 131. In the third balun 13, a portion of the secondary coil 132 overlaps a portion of the primary coil 131 in a plan view from the thickness direction D1 of the mounting board 1. In the present embodiment, the primary coil 131 includes one conductive portion 1313 (see FIG. 2) of the third conductive layer and one conductive portion 1314 (see FIG. 2) of the fourth conductive layer. The secondary coil 132 includes one conductive portion 1322 (see FIG. 2) of the second conductive layer. In the third balun 13, the number of turns of the primary coil 131 is two, and the number of turns of the secondary coil 132 is less than one. Note that the number of turns of the secondar coil 132 is not limited to being less than one, and may be one or more.

The first end 131a of the primary coil 131 of the third balun 13 is connected to the output terminal 252 of the fifth power amplifier 25. A second end of the primary coil 131 is connected to the power supply terminal T23 (see FIGS. 1 and 7). The first end 132a of the secondary coil 132 is connected to the input terminal 211 of the first power amplifier 21. The second end 132b of the secondary coil 132 is connected to the input terminal 221 of the second power amplifier 22.

In the fourth balun 14, the secondary coil 142 faces the primary coil 141 in the thickness direction D1 of the mounting board 1. In the present embodiment, in a plan view from the thickness direction D1 of the mounting board 1, a line width W142 (see FIG. 1) of the secondary coil 142 is the same as a line width W141 (see FIG. 1) of the primary coil 141. In the fourth balun 14, a portion of the secondary coil 142 overlaps a portion of the primary coil 141 in a plan view from the thickness direction D1 of the mounting board 1. In the present embodiment, the primary coil 141 includes one conductive portion 1411 (see FIG. 2) of the first conductive layer and one conductive portion 1413 (see FIG. 2) of the third conductive layer. The secondary coil 142 includes one conductive portion 1422 (see FIG. 2) of the second conductive layer. In the fourth balun 14, the number of turns of the primary coil 141 is two, and the number of turns of the secondary coil 142 is less than one. Note that the number of turns of the secondary coil 142 is not limited to being less than one, and may be one or more.

The first end 141a of the primary coil 141 of the fourth balun 14 is connected to the output terminal 262 of the sixth power amplifier 26. A second end of the primary coil 141 is connected to the power supply terminal T24 (see FIGS. 1 and 7). The first end of the secondary coil 142 is connected to the input terminal 231 of the third power amplifier 23. The second end of the secondary coil 142 is connected to the input terminal 241 of the fourth power amplifier 24.

In the fifth balun 15, the secondary coil 152 faces the primary coil 151 in the thickness direction D1 of the mounting board 1. In the fifth balun 15, a portion of the secondary coil 152 overlaps a portion of the primary coil 151 in a plan view from the thickness direction D1 of the mounting board 1.

In the sixth balun 16, the secondary coil 162 faces the primary coil 161 in the thickness direction D1 of the mounting board 1. In the sixth balun 16, a portion of the secondary coil 162 overlaps a portion of the primary coil 161 in a plan view from the thickness direction D1 of the mounting board 1.

### 2.2 Multiple Electronic Components

The multiple electronic components are disposed on the mounting board 1. In more detail, the multiple electronic components are disposed on the first main surface 101 (see FIGS. 3, 4, and 5) of the mounting board 1. The expression “the electronic component is disposed on the first main surface 101 of the mounting board 1” includes that the electronic component is mounted on (mechanically connected to) the first main surface 101 of the mounting board 1, and that the electronic component is electrically connected to (an appropriate pad electrode of) the mounting board 1. The multiple electronic components are mechanically and electrically connected to the first main surface 101 of the mounting board 1 by multiple joint portions, respectively. The multiple electronic components are circuit components of a radio-frequency circuit included in the radio-frequency module 100. The material of the joint portions respectively corresponding to the multiple electronic components is, for example, solder. The multiple joint portions may be elements of the electronic components, or may be elements interposed between the electronic components and the first main surface 101 of the mounting board 1.

In a plan view from the thickness direction D1 of the mounting board 1, the outer edge of each of the multiple electronic components has, for example, a rectangular shape. The multiple electronic components include, for example, the first IC chip 2, the second IC chip 3, and the third IC chip 4. The first IC chip 2 includes the first power amplifier 21, the second power amplifier 22, the third power amplifier 23, and the fourth power amplifier 24. The first IC chip 2 is a GaAs-based IC chip. In more detail, the first IC chip 2 is a GaAs-based IC chip that includes a GaAs substrate. The second IC chip 3 includes the fifth power amplifier 25, the sixth power amplifier 26, the ninth power amplifier 29, the control circuit 10, the first switch 5, and the second switch 6. The second IC chip 3 is a Si-based IC chip. In more detail, the second IC chip 3 is a Si-based IC chip including an SOI (Silicon on Insulator) substrate. The Si-based IC chip may include a silicon substrate instead of an SOI substrate. The third IC chip 4 includes the seventh power amplifier 27 and the eighth power amplifier 28. The third IC chip 4 is a Si-based IC chip. In more detail, the third IC chip 4 is a Si-based IC chip including an SOI substrate. The Si-based IC chip may include a silicon substrate instead of an SOI substrate.

The multiple electronic components also include the first inductor L1 and the first capacitor C1 of the first matching circuit M1, the second inductor L2 and the second capacitor C2 of the second matching circuit M2, and the third inductor L3 and the third capacitor C3 of the third matching circuit M3, as illustrated in FIG. 7.

The multiple electronic components further include a first duplexer, a second duplexer, a third duplexer, a fourth duplexer, and a fifth duplexer. The first duplexer includes the first transmission filter FT1 and the first reception filter FR1. The second duplexer includes the second transmission filter FT2 and the second reception filter FR2. The third duplexer includes the third transmission filter FT3 and the third reception filter FR3. The fourth duplexer includes the fourth transmission filter FT4 and the fourth reception filter FR4. The fifth duplexer includes the fifth transmission filter FT5 and the fifth reception filter FR5.

The multiple electronic components also include the third switch 7, circuit elements (inductor and capacitor) of the fourth matching circuit M11, circuit elements (inductor and capacitor) of the fifth matching circuit M12, and circuit elements (inductor and capacitor) of the sixth matching circuit M13.

The multiple electronic components further include components (a fifth IC chip including multiple low-noise amplifiers, circuit elements of an input matching circuit, etc.) of the low-noise amplification circuit. The low-noise amplification circuit includes a first low-noise amplifier that amplifies a first reception signal with low noise and outputs it, a second low-noise amplifier that amplifies a second reception signal with low noise and outputs it, a third low-noise amplifier that amplifies a third reception signal with low noise and outputs it, and a band selection switch. In the radio-frequency module 100, multiple external connection terminals include a first signal output terminal that outputs the first reception signal output from an output terminal of the first low-noise amplifier, a second signal output terminal that outputs the second reception signal output from an output terminal of the second low-noise amplifier, and a third signal output terminal that outputs the third reception signal output from an output terminal of the third low-noise amplifier.

As illustrated in FIGS. 1 and 5, an outer edge 20 of the first IC chip 2 has a rectangular shape in a plan view from the thickness direction D1 of the mounting board 1. The outer edge 20 of the first IC chip 2 includes a first side 201 and a second side 202 that are parallel to each other, and a third side 203 and a fourth side 204 that are parallel to each other. In a plan view from the thickness direction D1 of the mounting board 1, the first side 201, the third side 203, the second side 202, and the fourth side 204 are arranged in the order of the first side 201, the third side 203, the second side 202, and the fourth side 204. In a plan view, the first balun 11 is disposed at a first distance from the first side 201 of the IC chip 2, and the second balun 12 is disposed at a second distance from the first side 201, where the second distance is less than the first distance. The primary coil 111 of the first balun 11 defines a first footprint on the mounting board 1. The primary coil 121 of the second balun 12 is disposed entirely within the boundaries of the first footprint, or is positioned between the first balun 11 and the first side 201 of the IC chip. When a first axis is defined as being perpendicular to the first side 201 and passing through the center of the IC chip 2, the second balun 12 is interposed between the first balun 11 and the first side 201 along the first axis.

As illustrated in FIG. 6, an outer edge 30 of the second IC chip 3 has a rectangular shape in a plan view from the thickness direction D1 of the mounting board 1.

As illustrated in FIG. 6, an outer edge 40 of the third IC chip 4 has a rectangular shape in a plan view from the thickness direction D1 of the mounting board 1.

### 3 Layout

As illustrated in FIGS. 1 and 5, in the IC chip 2, the first side 201 and the second side 202 are long sides, and the third side 203 and the fourth side 204 are short sides. Thus, in a plan view from the thickness direction D1 of the mounting board 1, the longitudinal direction of the IC chip 2 is a direction along the first side 201. In a plan view from the thickness direction D1 of the mounting board 1, the aspect ratio (=[length of the long side]/[length of the short side]) of the rectangular-shaped outer edge 20 of the IC chip 2 is [length of the first side 201]/[length of the third side 203].

The IC chip 2 is arranged so that multiple connection terminals face (the first main surface 101 of) the mounting board 1. The multiple connection terminals include the input terminal 211, the output terminal 212, and the ground terminal 213 of the first power amplifier 21. The multiple connection terminals also include the input terminal 221, the output terminal 222, and the ground terminal 223 of the second power amplifier 22. The multiple connection terminals further include the input terminal 231, the output terminal 232, and the ground terminal 233 of the third power amplifier 23. Additionally, the multiple connection terminals include the input terminal 241, the output terminal 242, and the ground terminal 243 of the fourth power amplifier 24. Moreover, the multiple connection terminals include three control terminals connected to the control circuit 10.

In the IC chip 2, in a plan view from the thickness direction D1 of the mounting board 1, the output terminal 232 of the third power amplifier 23 and the output terminal 242 of the fourth power amplifier 24 are disposed along the first side 201. The expression “in a plan view from the thickness direction D1 of the mounting board 1, the output terminal 232 of the third power amplifier 23 and the output terminal 242 of the fourth power amplifier 24 are disposed along the first side 201” means that, in a plan view from the thickness direction D1 of the mounting board 1, the output terminal 232 of the third power amplifier 23 and the output terminals 242 of the fourth power amplifier 24 are disposed along the first side 201, without another or other connection terminals among the multiple connection terminals disposed between each of the output terminal 232 of the third power amplifier 23 and the output terminal 242 of the fourth power amplifier 24 and the first side 201. The output terminal 232 of the third power amplifier 23 and the output terminal 242 of the fourth power amplifier 24 are arranged in a direction parallel to the first side 201.

In the IC chip 2, in a plan view from the thickness direction D1 of the mounting board 1, the output terminal 212 of the first power amplifier 21 and the output terminal 222 of the second power amplifier 22 are farther from the first side 201 than the output terminal 232 of the third power amplifier 23 and the output terminal 242 of the fourth power amplifier 24. In the IC chip 2, the output terminal 212 of the first power amplifier 21 and the output terminal 232 of the third power amplifier 23 are arranged in the short-side direction orthogonal to the longitudinal direction of the IC chip 2. Additionally, in the IC chip 2, the output terminal 222 of the second power amplifier 22 and the output terminal 242 of the fourth power amplifier 24 are arranged in the short-side direction orthogonal to the longitudinal direction of the IC chip 2.

In the IC chip 2, in a plan view from the thickness direction D1 of the mounting board 1, the input terminal 231 of the third power amplifier 23 and the input terminal 241 of the fourth power amplifier 24 are arranged along the second side 202. The expression “in a plan view from the thickness direction D1 of the mounting board 1, the input terminal 231 of the third power amplifier 23 and the input terminal 241 of the fourth power amplifier 24 are disposed along the second side 202” means that, in a plan view from the thickness direction D1 of the mounting board 1, the input terminal 231 of the third power amplifier 23 and the input terminal 241 of the fourth power amplifier 24 are disposed along the second side 202, without another or other connection terminals among the multiple connection terminals disposed between each of the input terminal 231 of the third power amplifier 23 and the input terminal 241 of the fourth power amplifier 24 and the second side 202. The input terminal 231 of the third power amplifier 23 and the input terminal 241 of the fourth power amplifier 24 are arranged in a direction parallel to the second side 202.

In the IC chip 2, in a plan view from the thickness direction D1 of the mounting board 1, the input terminal 211 of the first power amplifier 21 and the input terminal 221 of the second power amplifier 22 are farther from the second side 202 than the input terminal 231 of the third power amplifier 23 and the input terminal 241 of the fourth power amplifier 24. In the IC chip 2, the input terminal 211 of the first power amplifier 21 and the input terminal 231 of the third power amplifier 23 are arranged in the short-side direction orthogonal to the longitudinal direction of the IC chip 2. Additionally, in the IC chip 2, the input terminal 221 of the second power amplifier 22 and the input terminal 241 of the fourth power amplifier 24 are arranged in the short-side direction orthogonal to the longitudinal direction of the IC chip 2.

In the IC chip 2, in a plan view from the thickness direction D1 of the mounting board 1, in a direction along the third side 203 (the short-side direction orthogonal to the longitudinal direction of the IC chip 2), the output terminal 232 of the third power amplifier 23, the ground terminal 233 of the third power amplifier 23, the output terminal 212 of the first power amplifier 21, the ground terminal 213 of the first power amplifier 21, the input terminal 211 of the first power amplifier 21, and the input terminal 231 of the third power amplifier 23 are arranged in the order of, from the first side 201, the output terminal 232 of the third power amplifier 23, the ground terminal 233 of the third power amplifier 23, the output terminal 212 of the first power amplifier 21, the ground terminal 213 of the first power amplifier 21, the input terminal 211 of the first power amplifier 21, and the input terminal 231 of the third power amplifier 23.

Additionally, in the IC chip 2, in a plan view from the thickness direction D1 of the mounting board 1, in a direction along the fourth side 204 (the short-side direction orthogonal to the longitudinal direction of the IC chip 2), the output terminal 242 of the fourth power amplifier 24, the ground terminal 243 of the fourth power amplifier 24, the output terminal 222 of the second power amplifier 22, the ground terminal 223 of the second power amplifier 22, the input terminal 221 of the second power amplifier 22, and the input terminal 241 of the fourth power amplifier 24 are arranged in the order of, from the first side 201, the output terminal 242 of the fourth power amplifier 24, the ground terminal 243 of the fourth power amplifier 24, the output terminal 222 of the second power amplifier 22, the ground terminal 223 of the second power amplifier 22, the input terminal 221 of the second power amplifier 22, and the input terminal 241 of the fourth power amplifier 24.

In a plan view from the thickness direction D1 of the mounting board 1, the second balun 12 is located on the inner side of the first balun 11. In a plan view from the thickness direction D1 of the mounting board 1, the primary coil 121 of the second balun 12 is located along the first side 201 of the IC chip 2.

In a plan view from the thickness direction D1 of the mounting board 1, the primary coil 111 of the first balun 11 intersects the third side 203 and the fourth side 204 of the IC chip 2, but does not intersect the first side 201 or the second side 202. Additionally, in a plan view from the thickness direction D1 of the mounting board 1, the secondary coil 112 of the first balun 11 intersects the third side 203 and the fourth side 204 of the IC chip 2, but does not intersect the first side 201 or the second side 202. Moreover, in a plan view from the thickness direction D1 of the mounting board 1, the primary coil 121 of the second balun 12 intersects the first side 201 of the IC chip 2, but does not intersect the second side 202, the third side 203, or the fourth side 204. Furthermore, in a plan view from the thickness direction D1 of the mounting board 1, the secondary coil 122 of the second balun 12 intersects none of the first side 201, the second side 202, the third side 203, or the fourth side 204 of the IC chip 2.

In a plan view from the thickness direction D1 of the mounting board 1, the fourth balun 14 is located on the inner side of the third balun 13. Additionally, in a plan view from the thickness direction D1 of the mounting board 1, the fourth balun 14 is located along the second side 202 of the IC chip 2. As used herein, the term “inner side” refers to a spatial relationship in plan view where a second component (e.g., the second balun 12) is positioned closer to a geometric center or a central longitudinal axis of the IC chip 2 than a first component (e.g., the first balun 11). Furthermore, “inner side” may describe a nested configuration wherein the second balun 12 is located within an area at least partially bounded by the coils of the first balun 11.

In a plan view from the thickness direction D1 of the mounting board 1, the primary coil 131 of the third balun 13 intersects the third side 203 and the fourth side 204 of the IC chip 2, but does not intersect the first side 201 or the second side 202. Additionally, in a plan view from the thickness direction D1 of the mounting board 1, the secondary coil 132 of the third balun 13 intersects the third side 203 and the fourth side 204 of the IC chip 2, but does not intersect the first side 201 or the second side 202. Moreover, in a plan view from the thickness direction D1 of the mounting board 1, the primary coil 141 of the fourth balun 14 intersects none of the first side 201, the second side 202, the third side 203, or the fourth side 204 of the IC chip 2. In addition, in a plan view from the thickness direction D1 of the mounting board 1, the secondary coil 142 of the fourth balun 14 intersects the second side 202 of the IC chip 2, but does not intersect the first side 201, the third side 203, or the fourth side 204. 4 Operation of First Power Amplifier, Second Power Amplifier, Third Power Amplifier, and Fourth Power Amplifier

The first power amplifier 21 is controlled by the control circuit 10 (see FIG. 7) and, and power-amplifies the first radio-frequency signal of the first frequency and outputs it. It is possible to check whether the first power amplifier 21 is power-amplifying the first radio-frequency signal of the first frequency and outputting it by measuring, with a network analyzer, the pass characteristics (the pass characteristics of the first transmission filter FT1 or the pass characteristics of the second transmission filter FT2) from the input terminal 211 of the first power amplifier 21 to the output terminal of the transmission filter (the first transmission filter FT1 or the second transmission filter FT2).

The second power amplifier 22 is controlled by the control circuit 10, and power-amplifies the second radio-frequency signal, which is a radio-frequency signal of the first frequency and opposite in phase to the first radio-frequency signal, and outputs it. It is possible to check whether the second power amplifier 22 is power-amplifying the second radio-frequency signal of the first frequency and outputting it by measuring, with a network analyzer, the pass characteristics (the pass characteristics of the first transmission filter FT1 or the pass characteristics of the second transmission filter FT2) from the input terminal 221 of the second power amplifier 22 to the output terminal of the transmission filter (the first transmission filter FT1 or the second transmission filter FT2).

The third power amplifier 23 is controlled by the control circuit 10, and power-amplifies the third radio-frequency signal of a second frequency higher than the first frequency and outputs it. It is possible to check whether the third power amplifier 23 is power-amplifying the third radio-frequency signal of the second frequency and outputting it by measuring, with a network analyzer, the pass characteristics (the pass characteristics of the third transmission filter FT3 or the pass characteristics of the fourth transmission filter FT4) from the input terminal 231 of the third power amplifier 23 to the output terminal of the transmission filter (the third transmission filter FT3 or the fourth transmission filter FT4).

The fourth power amplifier 24 is controlled by the control circuit 10, and power-amplifies the fourth radio-frequency signal, which is a radio-frequency signal of the second frequency and opposite in phase to the third radio-frequency signal, and outputs it. It is possible to check whether the fourth power amplifier 24 is power-amplifying the fourth radio-frequency signal of the second frequency and outputting it by measuring, with a network analyzer, the pass characteristics (the pass characteristics of the third transmission filter FT3 or the pass characteristics of the fourth transmission filter FT4) from the input terminal 241 of the fourth power amplifier 24 to the output terminal of the transmission filter (the third transmission filter FT3 or the fourth transmission filter FT4).

### 5 Communication Device

The communication device 500 includes, for example, the radio-frequency module 100 and the signal processing circuit 501 to which the radio-frequency module 100 is connected, as illustrated in FIG. 7. The communication device 500 further includes a first antenna AT1, a second antenna AT2, and a third antenna AT3. The communication device 500 further includes a motherboard on which the radio-frequency module 100 mounted. The motherboard is, for example, a printed wiring board. The motherboard has a ground electrode to which a ground potential is applied.

The radio-frequency module 100 is configured to be able to amplify the first transmission signal input from the signal processing circuit 501 and output it from the first antenna AT1, for example. The radio-frequency module 100 is also configured to be able to amplify the second transmission signal input from the signal processing circuit 501 and output it from the second antenna AT2. The radio-frequency module 100 is also configured to be able to amplify the third transmission signal input from the signal processing circuit 501 and output it from the third antenna AT3. Additionally, the radio-frequency module 100 is configured to be able to amplify the first reception signal input from the first antenna AT1 and output it to the signal processing circuit 501. The radio-frequency module 100 is also configured to be able to amplify the second reception signal input from the second antenna AT2 and output it to the signal processing circuit 501. The radio-frequency module 100 is further configured to be able to amplify the third reception signal input from the third antenna AT3 and output it to the signal processing circuit 501. The radio-frequency module 100 is, for example, controlled by the signal processing circuit 501 included in the communication device 500.

The signal processing circuit 501 includes the RF signal processing circuit 502 and a baseband signal processing circuit 503. The RF signal processing circuit 502 is, for example, an RFIC (Radio Frequency Integrated Circuit) and performs signal processing on radio-frequency signals. The RF signal processing circuit 502 performs signal processing, such as up-conversion, on a radio-frequency signal (transmission signal) output from the baseband signal processing circuit 503, and outputs the signal-processed radio-frequency signal. The RF signal processing circuit 502 also performs signal processing, such as down-conversion, on a radio-frequency signal (reception signal) output from the radio-frequency module 100, and outputs the signal-processed radio-frequency signal to the baseband signal processing circuit 503. The baseband signal processing circuit 503 is, for example, a BBIC (Baseband Integrated Circuit). The baseband signal processing circuit 503 generates an I-phase signal and a Q-phase signal from a baseband signal. The baseband signal is, for example, an audio signal or an image signal input from the outside. The baseband signal processing circuit 503 performs IQ modulation processing by combining the I-phase signal and the Q-phase signal, and outputs a transmission signal. At this time, the transmission signal is generated as a modulated signal (IQ signal) obtained by amplitude-modulating a carrier signal of a predetermined frequency with a period longer than the period of the carrier signal. The reception signal processed by the baseband signal processing circuit 503 is, for example, used as an image signal for displaying an image or as an audio signal for a call of the user of the communication device 500.

### 6 Effects

The radio-frequency module 100 according to Embodiment 1 includes the mounting board 1 and the IC chip 2. The IC chip 2 is disposed on the mounting board 1. The IC chip 2 includes the first power amplifier 21, the second power amplifier 22, the third power amplifier 23, and the fourth power amplifier 24. The first power amplifier 21 amplifies a first radio-frequency signal of a first frequency. The second power amplifier 22 amplifies a second radio-frequency signal that has the same frequency as the first frequency and is opposite in phase to the first radio-frequency signal. The third power amplifier 23 amplifies a third radio-frequency signal of a second frequency higher than the first frequency. The fourth power amplifier 24 amplifies a fourth radio-frequency signal that has the same frequency as the second frequency and is opposite in phase to the third radio-frequency signal. The mounting board 1 includes the first balun 11 and the second balun 12. The first balun 11 includes the primary coil 111. The primary coil 111 of the first balun 11 is connected between the output terminal 212 of the first power amplifier 21 and the output terminal 222 of the second power amplifier 22. The second balun 12 includes the primary coil 121. The primary coil 121 of the second balun 12 is connected between the output terminal 232 of the third power amplifier 23 and the output terminal 242 of the fourth power amplifier 24. The first balun 11 further has the secondary coil 112 facing the primary coil 111 of the first balun 11 in the thickness direction D1 of the mounting board 1. The second balun 12 further has the secondary coil 122 facing the primary coil 121 of the second balun 12 in the thickness direction D1 of the mounting board 1. In a plan view from the thickness direction D1 of the mounting board 1, the outer edge 20 of the IC chip 2 has a rectangular shape. The outer edge 20 of the first IC chip 2 includes the first side 201 and the second side 202 parallel to each other, and the third side 203 and the fourth side 204 parallel to each other. In a plan view from the thickness direction D1 of the mounting board 1, the second balun 12 is located on the inner side of the first balun 11. In a plan view from the thickness direction D1 of the mounting board 1, the primary coil 121 of the second balun 12 is located along the first side 201 of the IC chip 2. In the IC chip 2, the output terminal 232 of the third power amplifier 23 and the output terminal 242 of the fourth power amplifier 24 are disposed along the first side 201, and the output terminal 212 of the first power amplifier 21 and the output terminal 222 of the second power amplifier 22 are farther from the first side 201 than the output terminal 232 of the third power amplifier 23 and the output terminal 242 of the fourth power amplifier 24.

According to the above configuration, it is possible to suppress an increase in the plan-view aspect ratio of the IC chip 2 including the four power amplifiers (first power amplifier 21, second power amplifier 22, third power amplifier 23, and fourth power amplifier 24). In more detail, according to the above configuration, in the IC chip 2, the output terminal 232 of the third power amplifier 23 and the output terminal 242 of the fourth power amplifier 24 are disposed along the first side 201, and the output terminal 212 of the first power amplifier 21 and the output terminal 222 of the second power amplifier 22 are farther from the first side 201 than the output terminal 232 of the third power amplifier 23 and the output terminal 242 of the fourth power amplifier 24; thus, it is possible to suppress an increase in the plan-view aspect ratio of the IC chip 2, as compared with a case in which the four power amplifiers are arranged in one direction in an IC chip. Therefore, according to the above configuration, it is possible to suppress an increase in the plan-view aspect ratio of the IC chip 2 including the first power amplifier 21, the second power amplifier 22, the third power amplifier 23, and the fourth power amplifier 24. Additionally, according to the above configuration, in a plan view from the thickness direction D1 of the mounting board 1, the second balun 12 is located on the inner side of the first balun 11, and the primary coil 121 of the second balun 12 is located along the first side 201 of the IC chip 2; thus, it is possible to reduce the area occupied by the first balun 11 and the second balun 12, which in turn makes it possible to reduce the size of the radio-frequency module 100.

In the radio-frequency module 100 according to Embodiment 1, the line width W111 of the primary coil 111 of the first balun 11 is smaller than the line width W121 of the primary coil 121 of the second balun 12.

According to the above configuration, it is possible to reduce the area occupied by the first balun 11 in a plan view from the thickness direction D1 of the mounting board 1 while ensuring the length of the primary coil 111 for realizing a required inductance of the primary coil 111 of the first balun 11. Although it is necessary to make the inductance of the primary coil 111 of the first balun 11 greater than the inductance of the second balun 12, since the primary coil 111 of the first balun 11 is located on the outer side of the primary coil 121 of the second balun 12, it is possible to make the inductance of the primary coil 111 of the first balun 11 greater than the inductance of the primary coil 121 of the second balun 12. In the above configuration, it is possible to reduce the area occupied by the first balun 11 in a plan view from the thickness direction D1 of the mounting board 1 while ensuring the length of the primary coil 111 of the first balun 11. Accordingly, it is possible to reduce the size of the radio-frequency module 100 according to Embodiment 1.

Additionally, the radio-frequency module 100 according to Embodiment 1 further includes the fifth power amplifier 25, the sixth power amplifier 26, the first power supply terminal (power supply terminal T23), and the second power supply terminal (power supply terminal T24). The fifth power amplifier 25 is disposed on the mounting board 1. The sixth power amplifier 26 is disposed on the mounting board 1. The first power supply terminal (power supply terminal T23) is disposed on the mounting board 1. The second power supply terminal (power supply terminal T24) is disposed on the mounting board 1. The mounting board 1 further includes the third balun 13 and the fourth balun 14. The third balun 13 has the primary coil 131 and a secondary coil 132. The primary coil 131 of the third balun 13 is connected between the output terminal 252 of the fifth power amplifier 25 and the first power supply terminal (power supply terminal T23). The secondary coil 132 of the third balun 13 is connected between the input terminal 211 of the first power amplifier 21 and the input terminal 221 of the second power amplifier 22. The fourth balun 14 has the primary coil 141 and the secondary coil 142. The primary coil 141 of the fourth balun 14 is connected between the output terminal 262 of the sixth power amplifier 26 and the second power supply terminal (power supply terminal T24). The secondary coil 142 of the fourth balun 14 is connected between the input terminal 231 of the third power amplifier 23 and the input terminal 241 of the fourth power amplifier 24. In a plan view from the thickness direction D1 of the mounting board 1, the fourth balun 14 is located on the inner side of the third balun 13.

According to the above configuration, since the fifth power amplifier 25 and the third balun 13 are provided, the first transmission signal is amplified by the fifth power amplifier 25 and then converted by the third balun 13 into the first radio-frequency signal and the second radio-frequency signal. The first radio-frequency signal is amplified by the first power amplifier 21, and the second radio-frequency signal is amplified by the second power amplifier 22. This makes it possible to differentially amplify the first transmission signal. Additionally, according to the above configuration, since the sixth power amplifier 26 and the fourth balun 14 are provided, the second transmission signal is amplified by the sixth power amplifier 26 and then converted by the fourth balun 14 into the third radio-frequency signal and the fourth radio-frequency signal. The third radio-frequency signal is amplified by the third power amplifier 23, and the fourth radio-frequency signal is amplified by the fourth power amplifier 24. This makes it possible to differentially amplify the second transmission signal. Furthermore, according to the above configuration, since the fourth balun 14 is located on the inner side of the third balun 13 in a plan view from the thickness direction D1 of the mounting board 1, it is possible to achieve miniaturization.

In the radio-frequency module 100 according to Embodiment 1, the fourth balun 14 is located along the second side 202 of the IC chip 2 in a plan view from the thickness direction D1 of the mounting board 1.

According to the above configuration, it is possible to suppress an increase in the aspect ratio of the IC chip 2. Additionally, according to the above configuration, it is possible to reduce the area occupied by the fourth balun 14 in a plan view from the thickness direction D1 of the mounting board 1.

The radio-frequency module 100 according to Embodiment 1 further includes the second IC chip 3. The second IC chip 3 is different from the first IC chip 2, which is the IC chip 2. The second IC chip 3 is disposed on the mounting board 1. The fifth power amplifier 25 and the sixth power amplifier 26 are included in the second IC chip 3.

According to the above configuration, it is possible to reduce the size and cost of the radio-frequency module 100, as compared with a case in which the fifth power amplifier 25 and the sixth power amplifier 26 are separate chips.

In the radio-frequency module 100 according to Embodiment 1, the second IC chip 3 is a Si-based IC chip, and the first IC chip 2 is a GaAs-based IC chip.

According to the above configuration, as compared with a case where the second IC chip 3 is a GaAs-based IC chip, it is possible to achieve a low cost while ensuring a necessary gain for each of the fifth power amplifier 25 and the sixth power amplifier 26.

The communication device 500 according to Embodiment 1 includes the radio-frequency module 100 and the signal processing circuit 501. The signal processing circuit 501 is connected to the radio-frequency module 100.

According to the above configuration, in the radio-frequency module 100, it is possible to suppress an increase in the plan-view aspect ratio of the IC chip 2 including the four power amplifiers (first power amplifier 21, second power amplifier 22, third power amplifier 23, and fourth power amplifier 24).

### Embodiment 2

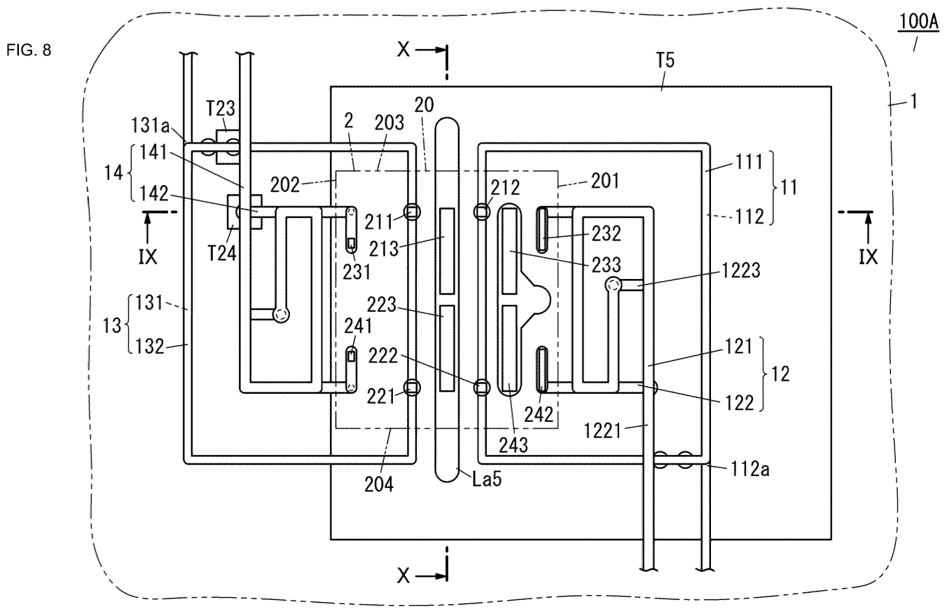

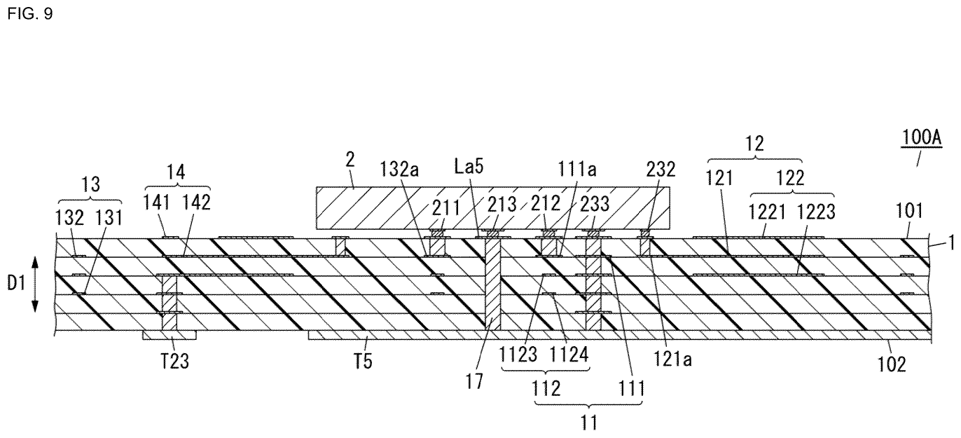

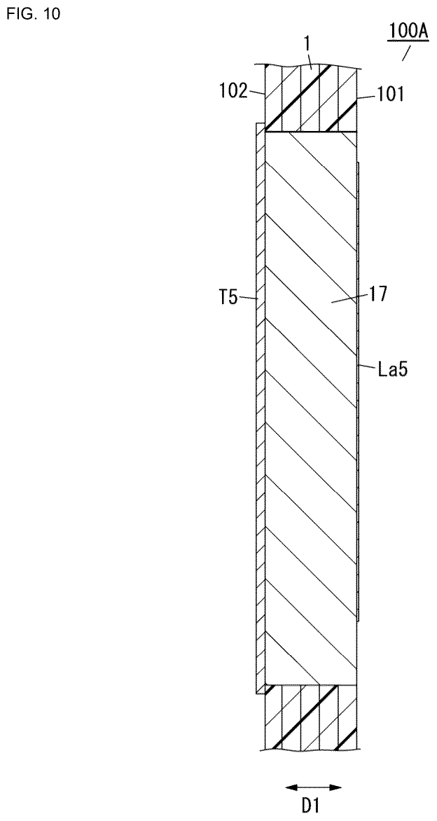

A radio-frequency module 100A according to Embodiment 2 will be described with reference to FIGS. 8 to 10. Regarding the radio-frequency module 100A according to Embodiment 2, elements that are the same as or similar to those of the radio-frequency module 100 according to Embodiment 1 (see FIGS. 1 to 7) are given the same reference numerals, and descriptions thereof are omitted.

### 1 Configuration

The radio-frequency module 100A according to Embodiment 2 differs from the radio-frequency module 100 according to Embodiment 1 in the point that the mounting board 1 includes a ground via conductor 17.

The ground via conductor 17 is connected to the ground terminal 213 of the first power amplifier 21 and the ground terminal 223 of the second power amplifier 22 and is located along the thickness direction D1 of the mounting board 1. The material of the ground via conductor 17 includes, for example, copper. In the mounting board 1, the ground via conductor 17 connects a land electrode La5 on the first main surface 101 side and the ground terminal T5 on the second main surface 102 side of the mounting board 1. The land electrode La5 is an electrode to which the ground terminal 213 of the first power amplifier 21 and the ground terminal 223 of the second power amplifier 22 are connected.

In a plan view from the thickness direction D1 of the mounting board 1, the ground via conductor 17 is located between the third balun 13 and the first balun 11 and is spaced apart from the third balun 13 and the first balun 11. In a plan view direction from the thickness direction D1 of the mounting board 1, the ground via conductor 17 has an elongated shape where the length in a direction along the first side 201 of the IC chip 2 is longer than the length in a direction along the third side 203 of the IC chip 2. In the present embodiment, in a plan view from the thickness direction D1 of the mounting board 1, the length of the ground via conductor 17 in a direction parallel to the first side 201 of the IC chip 2 is longer than the length of the first balun 11 and is longer than the length of the third balun 13. In a plan view from the thickness direction D1 of the mounting board 1, the ground via conductor 17 intersects the third side 203 and the fourth side 204 of the IC chip 2, and does not intersect the first side 201 or the second side 202 of the IC chip 2.

### 2 Effects

Like the radio-frequency module 100 according to Embodiment 1, the radio-frequency module 100A according to Embodiment 2 is capable of suppressing an increase in the plan-view aspect ratio of the IC chip 2 including the four power amplifiers (first power amplifier 21, second power amplifier 22, third power amplifier 23, and fourth power amplifier 24).

Additionally, in the radio-frequency module 100A according to Embodiment 2, the mounting board 1 further includes the ground via conductor 17. The ground via conductor 17 is connected to the ground terminal 213 of the first power amplifier 21 and the ground terminal 223 of the second power amplifier 22 and is located along the thickness direction D1 of the mounting board 1. In a plan view from the thickness direction D1 of the mounting board 1, the ground via conductor 17 is located between the third balun 13 and the first balun 11 and is spaced apart from the third balun 13 and the first balun 11.

According to the above configuration, with the ground via conductor 17, it is possible to improve isolation between the first balun 11 and the third balun 13.

### Embodiment 3

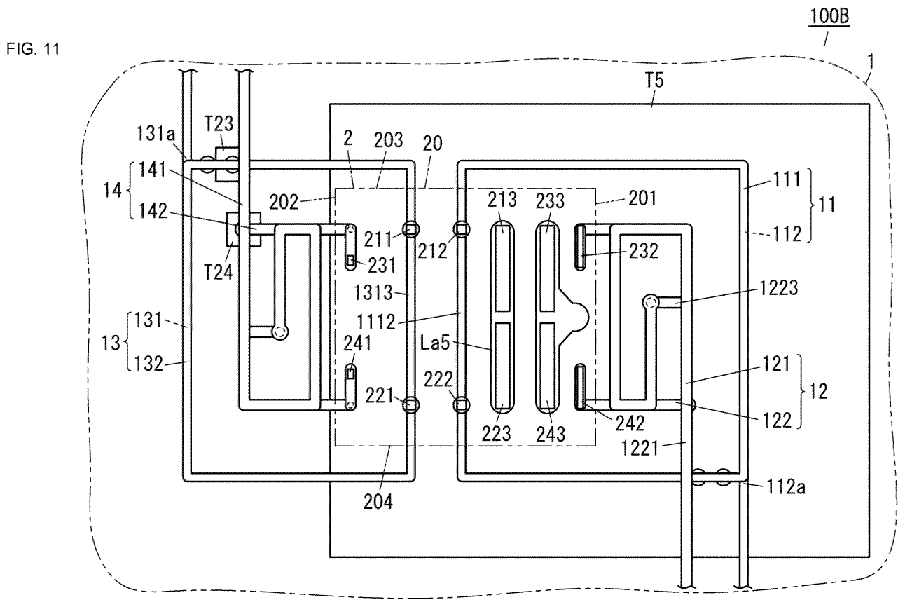

A radio-frequency module 100B according to Embodiment 3 will be described with reference to FIG. 11. Regarding the radio-frequency module 100B according to Embodiment 3, elements that are the same as or similar to those of the radio-frequency module 100 according to Embodiment 1 (see FIGS. 1 to 7) are given the same reference numerals, and descriptions thereof are omitted.

### 1 Configuration

The radio-frequency module 100B according to Embodiment 3 differs from the radio-frequency module 100 according to Embodiment 1 in the point that the layout of multiple connection terminals of the IC chip 2 is different.

In the IC chip 2 included in the radio-frequency module 100B of Embodiment 3, in a direction along the third side 203, the output terminal 232 of the third power amplifier 23, the ground terminal 233 of the third power amplifier 23, the ground terminal 213 of the first power amplifier 21, and the output terminal 212 of the first power amplifier 21 are arranged in the order of the output terminal 232 of the third power amplifier 23, the ground terminal 233 of the third power amplifier 23, the ground terminal 213 of the first power amplifier 21, and the output terminal 212 of the first power amplifier 21. In the IC chip 2, the ground terminal 233 of the third power amplifier 23 and the ground terminal 213 of the first power amplifier 21 are adjacent in a direction along the third side 203. The expression “the ground terminal 233 of the third power amplifier 23 and the ground terminal 213 of the first power amplifier 21 are adjacent in a direction along the third side 203” means that the ground terminal 233 of the third power amplifier 23 and the ground terminal 213 of the first power amplifier 21 are spaced apart in a direction along the third side 203, without another or other connection terminals among the multiple connection terminals disposed between the ground terminal 233 and the ground terminal 213.

In the IC chip 2, in a direction along the fourth side 204, the output terminal 242 of the fourth power amplifier 24, the ground terminal 243 of the fourth power amplifier 24, the ground terminal 223 of the second power amplifier 22, and the output terminal 222 of the second power amplifier 22 are arranged in the order of the output terminal 242 of the fourth power amplifier 24, the ground terminal 243 of the fourth power amplifier 24, the ground terminal 223 of the second power amplifier 22, and the output terminal 222 of the second power amplifier 22. In the IC chip 2, the ground terminal 243 of the fourth power amplifier 24 and the ground terminal 223 of the second power amplifier 22 are adjacent in a direction along the fourth side 204. The expression “the ground terminal 243 of the fourth power amplifier 24 and the ground terminal 223 of the second power amplifier 22 are adjacent in a direction along the fourth side 204” means that the ground terminal 243 of the fourth power amplifier 24 and the ground terminal 223 of the second power amplifier 22 are spaced apart in a direction along the fourth side 204, without another or other connection terminals among the multiple connection terminals disposed between the ground terminal 243 and the ground terminal 223.

### 2 Effects

Like the radio-frequency module 100 according to Embodiment 1, the radio-frequency module 100B according to Embodiment 3 is capable of suppressing an increase in the plan-view aspect ratio of the IC chip 2 including the four power amplifiers (first power amplifier 21, second power amplifier 22, third power amplifier 23, and fourth power amplifier 24).

Additionally, in the IC chip 2 of the radio-frequency module 100B according to Embodiment 3, in a direction along the third side 203, the output terminal 232 of the third power amplifier 23, the ground terminal 233 of the third power amplifier 23, the ground terminal 213 of the first power amplifier 21, and the output terminal 212 of the first power amplifier 21 are arranged in the order of the output terminal 232 of the third power amplifier 23, the ground terminal 233 of the third power amplifier 23, the ground terminal 213 of the first power amplifier 21, and the output terminal 212 of the first power amplifier 21. In the IC chip 2, in a direction along the fourth side 204, the output terminal 242 of the fourth power amplifier 24, the ground terminal 243 of the fourth power amplifier 24, the ground terminal 223 of the second power amplifier 22, and the output terminal 222 of the second power amplifier 22 are arranged in the order of the output terminal 242 of the fourth power amplifier 24, the ground terminal 243 of the fourth power amplifier 24, the ground terminal 223 of the second power amplifier 22, and the output terminal 222 of the second power amplifier 22.

According to the above configuration, the distance between the output terminal 232 of the third power amplifier 23 and the output terminal 212 of the first power amplifier 21 in a direction along the third side 203 may be increased. Thus, isolation between the output terminal 232 of the third power amplifier 23 and the output terminal 212 of the first power amplifier 21 may be improved. Furthermore, according to the above configuration, the width of each of the ground terminal 233 of the third power amplifier 23 and the ground terminal 213 of the first power amplifier 21 in a direction along the third side 203 may be increased, such that heat dissipation performance for heat generated by the IC chip 2 may be improved. Moreover, according to the above configuration the distance between the output terminal 242 of the fourth power amplifier 24 and the output terminal 222 of the second power amplifier 22 in a direction along the fourth side 204 may be improved, allowing isolation between the output terminal 242 of the fourth power amplifier 24 and the output terminal 222 of the second power amplifier 22 to be improved. Furthermore, according to the above configuration, the width of the ground terminal 243 of the fourth power amplifier 24 and the ground terminal 223 of the second power amplifier 22 in a direction along the fourth side 204 may be increased, allowing heat dissipation performance for heat generated by the IC chip 2 to be improved.

### Embodiment 4

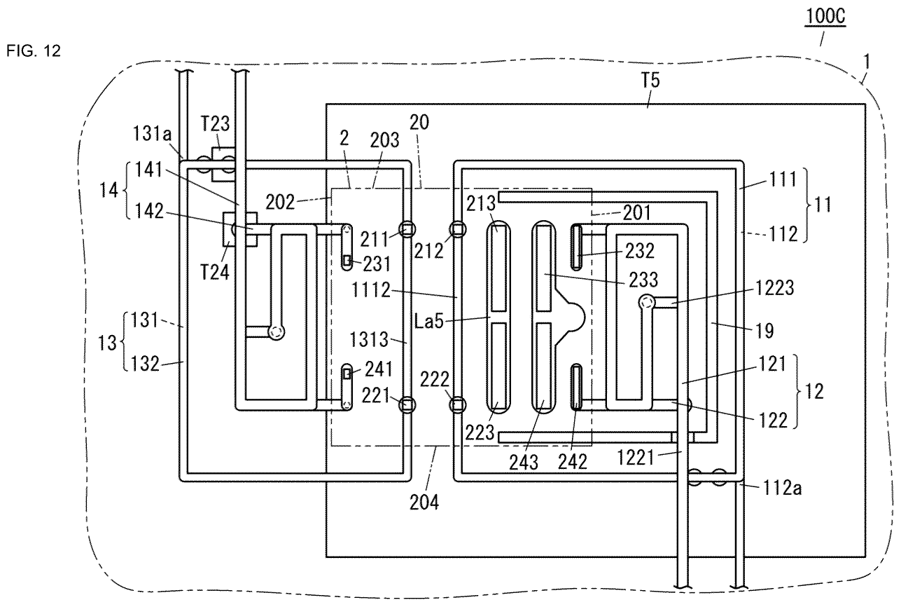

A radio-frequency module 100C according to Embodiment 4 will be described with reference to FIG. 12. Regarding the radio-frequency module 100C according to Embodiment 4, elements that are the same as or similar to those of the radio-frequency module 100 according to Embodiment 1 (see FIGS. 1 to 7) are given the same reference numerals, and descriptions thereof are omitted.

### 1 Configuration

The radio-frequency module 100C according to Embodiment 4 differs from the radio-frequency module 100 according to Embodiment 1 in the point that the mounting board 1 includes a ground electrode 19 disposed between the first balun 11 and the second balun 12 in a plan view from the thickness direction D1 of the mounting board 1.

The ground electrode 19 is disposed between the first balun 11 and the second balun 12 in a plan view from the thickness direction D1 of the mounting board 1. The ground electrode 19 is spaced apart from the first balun 11 and the second balun 12. In the example illustrated in FIG. 12, in a plan view from the thickness direction D1 of the mounting board 1, the secondary coil 112 of the first balun 11 has a rectangular frame shape, and the ground electrode 19 has a C shape along three of the four sides of the secondary coil 112 of the first balun 11. The shapes of the first balun 11, the second balun 12, and the ground electrode 19 in a plan view from the thickness direction D1 of the mounting board 1 are not limited to the example illustrated in FIG. 12.

The ground electrode 19 is, for example, disposed across the first main surface 101 and the second main surface 102 of the mounting board 1. The ground electrode 19 is, but not limited to, a single ground via conductor; it may be configured to include multiple conductor portions and multiple vias. Additionally, the thickness of the ground electrode 19 in the thickness direction D1 of the mounting board 1 may be thinner than the thickness of the mounting board 1.

### 2 Effects

Like the radio-frequency module 100 according to Embodiment 1, the radio-frequency module 100C according to Embodiment 4 is capable of suppressing an increase in the plan-view aspect ratio of the IC chip 2 including the four power amplifiers (first power amplifier 21, second power amplifier 22, third power amplifier 23, and fourth power amplifier 24).

Additionally, in the radio-frequency module 100C according to Embodiment 4, the mounting board 1 further includes the ground electrode 19. The ground electrode 19 is disposed between the first balun 11 and the second balun 12 in a plan view from the thickness direction D1 of the mounting board 1. The ground electrode 19 is spaced apart from the first balun 11 and the second balun 12.

According to the above configuration, it is possible to improve isolation between the first balun 11 and the second balun 12. This makes it difficult for harmonic waves of the first frequency from the first balun 11 to couple into the second balun 12, allowing noise in signals of the second frequency (such as the third radio-frequency signal, the fourth radio-frequency signal to be reduced, and a signal obtained by combining the third radio-frequency signal and the fourth radio-frequency signal).

### Embodiment 5

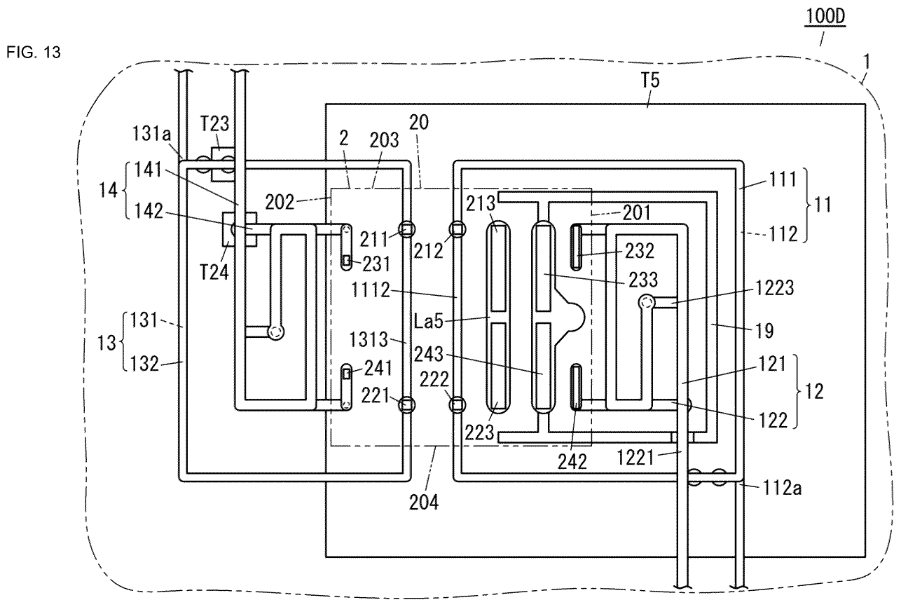

A radio-frequency module 100D according to Embodiment 5 will be described with reference to FIG. 13. Regarding the radio-frequency module 100D according to Embodiment 5, elements that are the same as or similar to those of the radio-frequency module 100C according to Embodiment 4 (see FIG. 12) are given the same reference numerals, and descriptions thereof are omitted.

### 1 Configuration

The radio-frequency module 100D according to Embodiment 5 differs from the radio-frequency module 100C according to Embodiment 4 in the point that the ground electrode 19 is connected to the ground terminal 233 of the third power amplifier 23 and the ground terminal 243 of the fourth power amplifier 24.

### 2 Effects

The radio-frequency module 100D according to Embodiment 5 achieves effects that are the same as or similar to those of the radio-frequency module 100C according to Embodiment 4.

### 3 Modification Example

The ground electrode 19 may be connected to the ground terminal 213 of the first power amplifier 21 and the ground terminal 223 of the second power amplifier 22, instead of being connected to the ground terminal 233 of the third power amplifier 23 and the ground terminal 243 of the fourth power amplifier 24.

### Embodiment 6

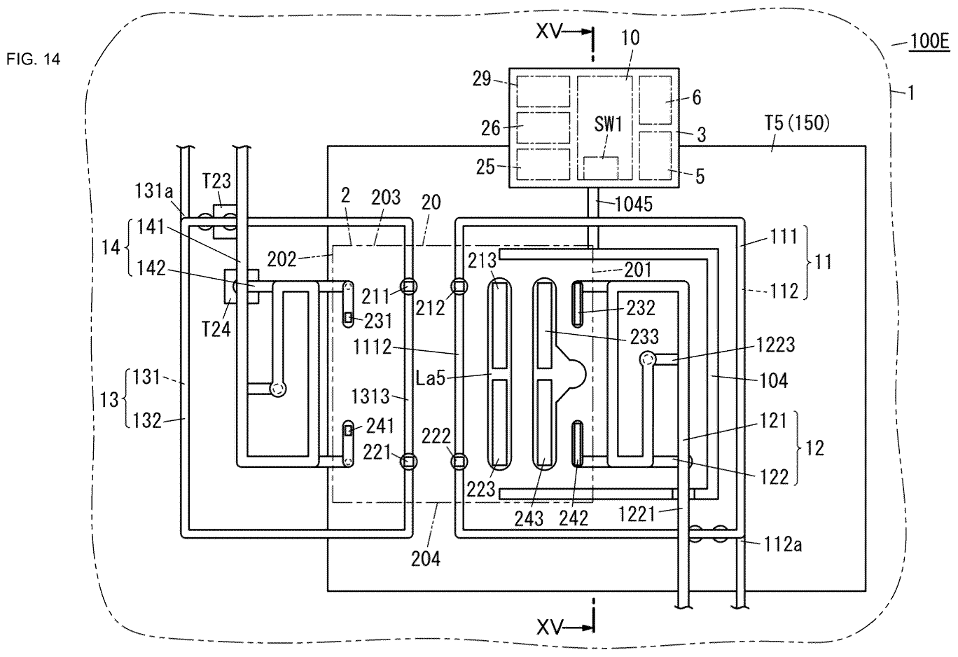

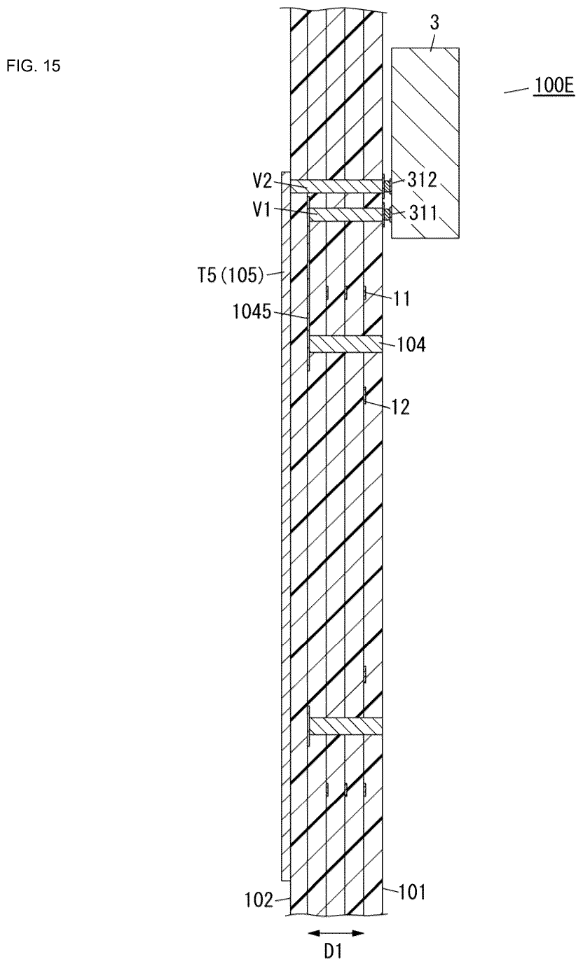

A radio-frequency module 100E according to Embodiment 6 will be described with reference to FIGS. 14 and 15. Regarding the radio-frequency module 100E according to Embodiment 6, elements that are the same as or similar to those of the radio-frequency module 100C according to Embodiment 4 (see FIG. 12) are given the same reference numerals, and descriptions thereof are omitted.

### 1 Configuration

The radio-frequency module 100E according to Embodiment 6 differs from the radio-frequency module 100C according to Embodiment 4 in the point that the mounting board 1 includes a floating electrode 104 disposed between the first balun 11 and the second balun 12 in a plan view from the thickness direction D1 of the mounting board 1, and a switch SW1. Note that the ground terminal T5 constitutes a ground electrode 105 in the present embodiment.

The floating electrode 104 is disposed between the first balun 11 and the second balun 12 in a plan view from the thickness direction D1 of the mounting board 1, and is spaced apart from the first balun 11 and the second balun 12.

In the example illustrated in FIG. 14, in a plan view from the thickness direction D1 of the mounting board 1, the secondary coil 112 of the first balun 11 has a rectangular frame shape, and the floating electrode 104 has a C shape along three of the four sides of the secondary coil 112 of the first balun 11. The shapes of the first balun 11, the second balun 12, and the floating electrode 104 in a plan view from the thickness direction D1 of the mounting board 1 are not limited to the example illustrated in FIG. 14.

The ground electrode 105 is, for example, disposed on the second main surface 102 side of the mounting board 1.

The switch SW1 is disposed on the mounting board 1 and is connected between the floating electrode 104 and the ground electrode 105. The switch SW1 has a first terminal 311 and a second terminal 312. The first terminal 311 of the switch SW1 is connected to the floating electrode 104 with a via conductor V1 and a conductor portion 1045 of the mounting board 1 interposed therebetween. The second terminal 312 of the switch SW1 is connected to the ground electrode 105 with a via conductor V2 of the mounting board 1 interposed therebetween. The floating electrode 104 is isolated from the ground electrode 105 and set to a floating potential. When the switch SW1 is on, the floating electrode 104 is grounded to the ground electrode 105 and is set to a ground potential. When the switch SW1 is off, the switch SW1 is, but is not limited to, for example, an FET, and may be a bipolar transistor. Additionally, in the present embodiment, the switch SW1 is included in the control circuit 10 of the second IC chip 3. Like the second IC chip 3 of Embodiment 1, the second IC chip 3 includes the fifth power amplifier 25, the sixth power amplifier 26, the ninth power amplifier 29, the control circuit 10, the first switch 5, and the second switch 6.

### 2 Operation of Control Circuit

Like the control circuit 10 of the radio-frequency module 100 according to Embodiment 1, the control circuit 10 controls, for example, the first power amplifier 21, the second power amplifier 22, the third power amplifier 23, the fourth power amplifier 24, the fifth power amplifier 25, the sixth power amplifier 26, the seventh power amplifier 27, the eighth power amplifier 28, and the ninth power amplifier 29 in accordance with control signals from the signal processing circuit 501.

The operation of the control circuit 10 in the radio-frequency module 100E according to Embodiment 6 differs from the operation of the control circuit 10 in the radio-frequency module 100 according to Embodiment 1 in the point that the control circuit 10 in the radio-frequency module 100E also controls the switch SW1 in accordance with a control signal from the signal processing circuit 501.

To power-amplify the first transmission signal by the first power amplification circuit PA1, the control circuit 10 operates the first power amplifier 21 and the second power amplifier 22 simultaneously. To power-amplify the second transmission signal by the second power amplification circuit PA2, the control circuit 10 operates the third power amplifier 23 and the fourth power amplifier 24 simultaneously. In order to simultaneously transmit the first transmission signal and the second transmission signal, the control circuit 10 operates the first power amplifier 21, the second power amplifier 22, the third power amplifier 23, and the fourth power amplifier 24 simultaneously. In order to simultaneously operate the first power amplifier 21 and the third power amplifier 23, the control circuit 10 turns on the switch SW1 so that the floating electrode 104 is grounded to the ground electrode 105. In order not to simultaneously operate the first power amplifier 21 and the third power amplifier 23, the control circuit 10 turns off the switch SW1 so that the floating electrode 104 is not grounded to the ground electrode 105.

### 3 Effects

The radio-frequency module 100E according to Embodiment 6 achieves effects that are the same as or similar to those of the radio-frequency module 100C according to Embodiment 4.

Additionally, in the radio-frequency module 100E according to Embodiment 6, the mounting board 1 further includes the floating electrode 104, the ground electrode 105, and the switch SW1. The floating electrode 104 is disposed between the first balun 11 and the second balun 12 in a plan view from the thickness direction D1 of the mounting board 1, and is spaced apart from the first balun 11 and the second balun 12. The switch SW1 is disposed on the mounting board 1 and is connected between the floating electrode 104 and the ground electrode 105.

According to the above configuration, when the switch SW1 is on, the floating electrode 104 is grounded to the ground electrode 105 and set to a ground potential; and when the switch SW1 is off, the floating electrode 104 is set to a floating potential.

Additionally, the radio-frequency module 100E according to Embodiment 6 includes the control circuit 10. The control circuit 10 is disposed on the mounting board 1. The control circuit 10 controls the first power amplifier 21, the second power amplifier 22, the third power amplifier 23, and the fourth power amplifier 24. The control circuit 10 operates the first power amplifier 21 and the second power amplifier 22 simultaneously. The control circuit 10 also operates the third power amplifier 23 and the fourth power amplifier 24 simultaneously. In order to simultaneously operate the first power amplifier 21 and the third power amplifier 23, the control circuit 10 turns on the switch SW1 so that the floating electrode 104 is grounded to the ground electrode 105. In order not to simultaneously operate the first power amplifier 21 and the third power amplifier 23, the control circuit 10 turns off the switch SW1 so that the floating electrode 104 is not grounded to the ground electrode 105.

According to the above configuration, when the control circuit 10 turns on switch SW1, the floating electrode 104 is grounded to the ground electrode 105 and set to a ground potential, thereby making it possible to improve isolation between the first balun 11 and the second balun 12 during simultaneous transmission. When the control circuit 10 turns off the switch SW1, the floating electrode 104 is set to a floating potential, thereby making it possible to reduce loss when simultaneous transmission is not performed.

### Other Modification Examples

Embodiments 1 to 6 and the like described above are merely examples of various embodiments of the present disclosure. Embodiments 1 to 6 and the like described above may be variously modified according to design factors and may be appropriately combined with each other.

For example, the circuit configuration of each of the first power amplification circuit PA1, the second power amplification circuit PA2, and the third power amplification circuit PA3 is not limited to the example illustrated in FIG. 5. For example, in each of the first power amplification circuit PA1, the second power amplification circuit PA2, and the third power amplification circuit PA3, the input signal (transmission signal) has been described as a single-ended signal; however, the input signal is not limited to a single-ended signal and may be, for example, a differential signal. In this case, the first power amplification circuit PA1 is not required to include the third balun 13. Similarly, the second power amplification circuit PA2 is not required to include the fourth balun 14. Likewise, the third power amplification circuit PA3 is not required to include the sixth balun 16.

Additionally, each of the first power amplification circuit PA1, the second power amplification circuit PA2, and the third power amplification circuit PA3 is not required to be a multi-stage amplification circuit. In this case, the first power amplification circuit PA1 is not required to include the fifth power amplifier 25. Similarly, the second power amplification circuit PA2 is not required to include the sixth power amplifier 26. Likewise, the third power amplification circuit PA3 is not required to include the ninth power amplifier 29.

The radio-frequency module 100 includes the low-noise amplification circuit, but may be configured without a low-noise amplification circuit. The radio-frequency module 100 includes the multiple reception filters FR1 to FR5, but may be configured without the multiple reception filters FR1 to FR5.

Furthermore, the radio-frequency modules 100 and 100A to 100E may be disposed on the first main surface 101 of the mounting board 1 and further include a resin layer that covers multiple electronic components. The resin layer has electrical insulation properties. The resin layer includes a resin (e.g., an epoxy resin). The resin layer may include a filler in addition to the resin. Moreover, the radio-frequency modules 100 and 100A to 100E may further include an external shield layer that covers the resin layer and the sides of the mounting board 1. The external shield layer has electrical conductivity. In the radio-frequency modules 100 and 100A to 100E, the external shield layer is provided, for example, for the purpose of electromagnetic shielding inside and outside the radio-frequency modules 100 and 100A to 100E. The external shield layer has a multilayer structure in which multiple metal layers are stacked; however, the external shield layer is not limited to a multilayer structure and may be a single metal layer. The metal layers include one or more types of metals. When the external shield layer has a multilayer structure in which multiple metal layers are stacked, it includes, for example, a first stainless steel layer, a Cu layer on the first stainless steel layer, and a second stainless steel layer on the Cu layer. The material of each of the first stainless steel layer and the second stainless steel layer is an alloy containing Fe, Ni, and Cr. When the external shield layer has a single metal layer, it is, for example, a Cu layer. The external shield layer is connected to a ground terminal with a ground layer and a ground via conductor of the mounting board 1 interposed therebetween.

The radio-frequency modules 100 and 100A to 100E are single-sided mounting modules where all of the electronic components are disposed on the first main surface 101 of the mounting board 1; however, the radio-frequency modules 100 and 100A to 100E may be double-sided mounting modules where some of the electronic components are disposed on the second main surface 102 of the mounting board 1.

The communication device 500 of Embodiment 1 may include any of the radio-frequency modules 100A to 100E instead of the radio-frequency module 100.

What is claimed is:

1. A radio-frequency module comprising:
a mounting board; and
an integrated circuit (IC) chip disposed on the mounting board,
wherein the IC chip includes:
a first power amplifier configured to amplify a first radio-frequency signal of a first frequency;
a second power amplifier configured to amplify a second radio-frequency signal that has a same frequency as the first frequency and is opposite in phase to the first radio-frequency signal;
a third power amplifier configured to amplify a third radio-frequency signal of a second frequency higher than the first frequency; and
a fourth power amplifier configured to amplify a fourth radio-frequency signal that has a same frequency as the second frequency and is opposite in phase to the third radio-frequency signal,
the mounting board includes:
a first balun having a primary coil connected between an output terminal of the first power amplifier and an output terminal of the second power amplifier; and
a second balun having a primary coil connected between an output terminal of the third power amplifier and an output terminal of the fourth power amplifier,
the first balun further includes a secondary coil that faces the primary coil of the first balun in a thickness direction of the mounting board,
the second balun further includes a secondary coil that faces the primary coil of the second balun in the thickness direction of the mounting board,
in a plan view from the thickness direction of the mounting board,
an outer edge of the IC chip has a rectangular shape defined by
a first side and a second side that are parallel to each other, and a third side and a fourth side that are parallel to each other,
the second balun is located on an inner side of the first balun, and
the primary coil of the second balun is located along the first side of the IC chip, and
in the IC chip,
the output terminal of the third power amplifier and the output terminal of the fourth power amplifier are disposed along the first side; and
the output terminal of the first power amplifier and the output terminal of the second power amplifier are farther from the first side than the output terminal of the third power amplifier and the output terminal of the fourth power amplifier.

2. The radio-frequency module according to claim 1, wherein:
a line width of the primary coil of the first balun is smaller than a line width of the primary coil of the second balun.

3. The radio-frequency module according to claim 1, further comprising:
a fifth power amplifier disposed on the mounting board;
a sixth power amplifier disposed on the mounting board;
a first power supply terminal disposed on the mounting board; and
a second power supply terminal disposed on the mounting board,
wherein the mounting board includes:
a third balun having a primary coil connected between an output terminal of the fifth power amplifier and the first power supply terminal, and a secondary coil connected between an input terminal of the first power amplifier and an input terminal of the second power amplifier; and
a fourth balun having a primary coil connected between an output terminal of the sixth power amplifier and the second power supply terminal, and a secondary coil connected between an input terminal of the third power amplifier and an input terminal of the fourth power amplifier, and
in the plan view from the thickness direction of the mounting board, the fourth balun is located on an inner side of the first balun.

4. The radio-frequency module according to claim 3, wherein:
in a plan view from the thickness direction of the mounting board, the fourth balun is located along the second side of the IC chip.

5. The radio-frequency module according to claim 3, wherein:
in the IC chip,
the input terminal of the third power amplifier and the input terminal of the fourth power amplifier are disposed along the second side; and
the input terminal of the first power amplifier and the input terminal of the second power amplifier are farther from the second side than the input terminal of the third power amplifier and the input terminal of the fourth power amplifier.

6. The radio-frequency module according to claim 3, wherein the IC chip is a first IC chip, further comprising:
a second IC chip disposed on the mounting board, the second IC chip being different from the first IC chip,
wherein the fifth power amplifier and the sixth power amplifier are included in the second IC chip.

7. The radio-frequency module according to claim 6, wherein:
the second IC chip is a Si-based IC chip; and
the first IC chip is a GaAs-based IC chip.

8. The radio-frequency module according to claim 3, wherein:
the mounting board further includes a ground via conductor connected to a ground terminal of the first power amplifier and a ground terminal of the second power amplifier, and located along the thickness direction of the mounting board; and
in the plan view from the thickness direction of the mounting board, the ground via conductor is located between the third balun and the first balun, and is spaced apart from the third balun and the first balun.

9. The radio-frequency module according to claim 3, wherein:
in the IC chip,
in a direction along the third side, the output terminal of the third power amplifier, a ground terminal of the third power amplifier, a ground terminal of the first power amplifier, and the output terminal of the first power amplifier are arranged in order of the output terminal of the third power amplifier, the ground terminal of the third power amplifier, the ground terminal of the first power amplifier, and the output terminal of the first power amplifier; and
in a direction along the fourth side, the output terminal of the fourth power amplifier, a ground terminal of the fourth power amplifier, a ground terminal of the second power amplifier, and the output terminal of the second power amplifier are arranged in order of the output terminal of the fourth power amplifier, the ground terminal of the fourth power amplifier, the ground terminal of the second power amplifier, and the output terminal of the second power amplifier.

10. The radio-frequency module according to claim 1, wherein:
the mounting board further includes:
a ground electrode that is disposed between the first balun and the second balun in a plan view from the thickness direction of the mounting board, and that is spaced apart from the first balun and the second balun.

11. The radio-frequency module according to claim 1, wherein:
the mounting board further includes:
a floating electrode that is disposed between the first balun and the second balun in a plan view from the thickness direction of the mounting board, and that is spaced apart from the first balun and the second balun; and
a ground electrode, and
the radio-frequency module further includes a switch disposed on the mounting board and connected between the floating electrode and the ground electrode.

12. The radio-frequency module according to claim 11, further comprising:
a control circuit that is disposed on the mounting board and in configured to control the first power amplifier, the second power amplifier, the third power amplifier, and the fourth power amplifier,
wherein the control circuit is configured to
simultaneously operate the first power amplifier and the second power amplifier,
simultaneously operate the third power amplifier and the fourth power amplifier simultaneously,
simultaneously operate the first power amplifier and the third power amplifier, by turning on the switch so that the floating electrode is grounded to the ground electrode, and
to prevent simultaneous operation of the first power amplifier and the third power amplifier, by turning off the switch so that the floating electrode is not grounded to the ground electrode.

13. The radio-frequency module according to claim 11, wherein, in the plan view, the floating electrode does not overlap the primary coil of the second balun or the secondary coil of the second balun.

14. The radio-frequency module according to claim 11, wherein, in the thickness direction, the primary coil of the first balun, the secondary coil of the first balun, and the floating electrode are located between the IC chip and the ground electrode.

15. The radio-frequency module according to claim 11, wherein the floating electrode faces the primary coil of the first balun with the secondary coil of the first balun interposed therebetween.

16. The radio-frequency module according to claim 1, wherein the secondary coil of the first balun and the secondary coil of the second balun are respectively connected to external output terminals disposed on a bottom surface of the mounting board.

17. The radio-frequency module according to claim 1, wherein the mounting board includes dielectric layers and a plurality of conductive layers stacked in the thickness direction, and the first balun and the second balun are integrated within the plurality of dielectric layers.

18. A communication device comprising:
the radio-frequency module according to claim 1; and
a signal processing circuit connected to the radio-frequency module.

19. An integrated circuit chip for use in a radio-frequency (RF) module, the IC chip comprising:
a rectangular outer edge in plan view defined by a first side and a second side parallel to each other, and a third side and a fourth side parallel to each other;
a first power amplifier and a second power amplifier configured to output a first differential signal of a first frequency; and
a third power amplifier and a fourth power amplifier configured to output a second differential signal of a second frequency higher than the first frequency, wherein an output terminal of the third power amplifier and an output terminal of the fourth power amplifier are disposed along the first side, and
an output terminal of the first power amplifier and an output terminal of the second power amplifier are disposed farther from the first side than the output terminals of the third and fourth power amplifiers.

20. A radio-frequency module comprising:
a mounting board including a first balun and a second balun; and
an integrated circuit (IC) chip mounted on the mounting board, the IC chip including a first pair of power amplifiers for a first frequency and a second pair of power amplifiers for a second frequency higher than the first frequency, wherein
the second balun is nested within an area at least partially surrounded by the first balun in a plan view, and
output terminals of the second pair of power amplifiers are positioned on the IC chip closer to an edge of the IC chip adjacent to the second balun than output terminals of the first pair of power amplifiers.
